(19) United States
(12) Patent Application Publication
(10) Pub. No.: US 2009/0304924 A1
(43) Pub. Date: Dec. 10, 2009

(54) APPARATUS AND METHOD FOR LARGE AREA MULTI-LAYER ATOMIC LAYER CHEMICAL VAPOR PROCESSING OF THIN FILMS

(76) Inventor: Prasad Gadgil, Santa Clara, CA (US)

Correspondence Address: BROOKS KUSHMAN P.C., 1000 TOWN CENTER, TWENTY-SECOND FLOOR, SOUTHFIELD, MI, 48075, US

(21) Appl. No.: 12/281,542

(22) PCT Filed: Mar. 3, 2006
(86) PCT No.: PCT/US06/07715

§ 371 Date: Feb. 2, 2009

(51) Int. Cl. C23C 16/44

(52) U.S. Cl. 427/255.5; 118/718

(57) ABSTRACT

An apparatus and method for large area high speed atomic layer chemical vapor processing wherein continuous and alternating streams of reactive and inert gases are directed towards a co-axially mounted rotating cylindrical susceptor from a plurality of composite nozzles placed around the perimeter of the processing chamber. A flexible substrate is mounted on the cylindrical susceptor. In one embodiment, the process reactor has four composite injectors arranged substantially parallel to the axis of rotation of the cylindrical susceptor. In the other embodiment, the susceptor cross section is a polygon with a plurality of substrates mounted on its facets. The reactor can be operated to process multiple flexible or flat substrates with a single atomic layer precision as well as high-speed chemical vapor processing mode. The atomic layer chemical vapor processing system of the invention also has provisions to capture unused portion of injected reactive chemical precursors downstream.

### CROSS REFERENCE TO RELATED APPLICATION

This application claims the benefit of the U.S. provisional application Ser. No. 60/656,772 filed Feb. 26, 2005 which is incorporated by reference herein.

### FIELD OF INVENTION

The present invention is in the area of apparatus and methods for chemical vapor phase processing of multi-layer thin films of various materials at one atomic layer precision. More, particularly, this invention relates to processing of multi-layer thin films at one atomic layer precision on flexible substrates at high-speed for manufacturing of semiconductor devices, large area thin-film photovoltaic solar cells, flexible displays and catalytic electrodes for fuel cells, among other applications.

### BACKGROUND OF THE RELATED ART

Thin film processing forms a critical part of fabrication of a variety of advanced devices such as microelectronic devices, optoelectronic and photonic devices, thin film photovoltaic solar cells and optical coatings and so on. In all these applications, invariably large-area processing uniformity along with high speed of processing is important to achieve economics of scale. A variety of techniques of thin film deposition such as chemical vapor deposition (CVD) and physical vapor deposition (PVD) are currently being practiced in the industry to deposit thin films of metals, semiconductors and insulators. These and associated techniques of thin film deposition are flux dependent and thus can offer much desired thin film uniformity on larger area substrates with significant challenges in the apparatus design and its operation and at higher cost. Although these techniques can deposit thin films at a high rate, ranging from several tens of nm/min to a few hundred nm/min., a glaring shortcoming is an inability to deposit high quality and conformal thin films in narrow, sub-micron geometrical features and film higher film thickness uniformity that is exceedingly difficult to achieve with increasing substrate area.

These inadequacies in the prevalent thin film deposition techniques are largely removed by a recent entrant to thin film deposition processes which is know in the art as Atomic Layer Deposition, or simply ALD, which was invented in mid 1970s but was not applied to microelectronic device fabrication until recently. ALD is a variant of CVD. An ALD process, based on a well-known principle of chemisorption, forms a strongly adherent monolayer of reactive gas molecules, and is thus self limiting and also independent of the area of the substrate. Moreover, ALD thin films are typically conformal, even in deep, sub-micron geometries of a substrate surface morphology. These are extremely powerful and much sought-after attributes for a variety of advance device processes. In a typical ALD process, excess physiosorbed gas molecules of the reactive gases, and also reaction by-products, are swept away by inert gas pulses from the vicinity of the substrate. All the gases are sequentially injected and spread over the entire substrate surface to form a monolayer of the thin film to be deposited. The substrate is appropriately heated or supplied in another manner with necessary activation energy to affect the overall reaction of chemisorption and chemical reaction to form the product thin film. An ALD process thus typically consists of four pulses including two inert gas pulses. The overall process sequence of four gas pulses is repeated to build the desired film thickness in a cyclic manner with a monolayer precision. A typical ALD process is schematically represented by a generic chemical reaction as shown in equation 1 below:

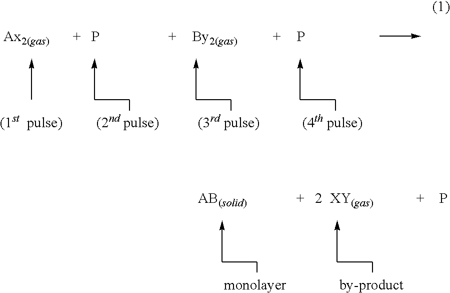

In an ALD process, the second pulse of inert gas P in reaction described above in equation (1) that is responsible for creating a chemisorbed monolayer of Ax₂ type specie on the surface of the substrate which then further reacts with reactive gaseous species By₂ to form a monolayer AB. The fourth pulse of the inert gas P removes the reaction by-products xy and also any excess of By₂. The inert gas pulses in the reaction described in equation (1) can be replaced by simple evacuation of the process chamber in order to remove excess of reactant Ax2 from the substrate surface, however, impingement of an inert gas improves the efficiency of dislodging the excess reactive gas Ax₂ (and also By₂ and the by-product of the overall chemical reaction—xy) from the vicinity of the substrate by imparting momentum. Moreover, an inert gas does not actively participate in the overall chemical reaction.

Yet another method of practicing an ALD process is to maintain a constant flow of inert gas in the chamber and intersperse reactive gas pulses with a sufficient time span between them. At the same time, removal of the second pulse or the fourth pulse or both of the inert gas (or even mere evacuation steps employed in lieu of inert gas pulses), will transform the overall reaction mechanism from an ALD type to high-rate CVD type. The overall process comprising four pulses should have been appropriately termed as a monolayer deposition process. However, atomic layer deposition has been prevalent since its inception and accepted thereafter. Fundamentals of the ALD process and also basic reactor hardware are described in U.S. Pat. No. 4,058,430 by Suntola et al., which is included in the present specification by reference.

In practice a typical ALD process is quite slow as compared to a conventional CVD process because the ALD process critically depends on the time taken to complete one ALD process cycle. The cycle time in ALD in turn depends upon the gas residence time (and also on non-turbulent gas flow) within the ALD reactor, in addition to the speed of operation of the gas pulsing mechanism and hardware, e.g., fast switching valves, their efficiency, reliability and useful lifetime are important factors. The gas residence times in an ALD reactor, which depend upon reactor volume, operating pressure and the gas flow rate, for large substrates measuring as much as 1 square meter, may reach up to several seconds, with resulting deposition rate of barely 1 nm/min. As a result, practical application of ALD to large area substrates is restricted to very thin films—such as a few tens of nanometers or below. This situation may be partly remedied by employing batch processing. However, batch processors are undesirable due to a variety of factors as substrate backside deposition, proportionately larger volume, and substrate load-unload time. Thus, the industry trend has been in favor of smaller-volume, single-substrate, or a mini-batch (four to five substrates per batch) ALD reactors. Therefore, for an efficient ALD reactor operation, a judicious choice has to be made by comparing the pros and cons of all these factors and their impact on the ALD cycle time to arrive at an optimized solution for a required application.

Multiple-wafer batch processors that can block backside deposition on the substrates have been prevalent in the area of epitaxial thin films of silicon and compound semiconductor thin films such as GaAs and others. One of the most successful reactor configurations for this purpose has been a barrel type reactor in which a number of substrates are mounted on the faces of a trapezoid shaped solid susceptor. The susceptor may be heated by means such as external lamps or by an inductive heating arrangement. The reactive gases are typically introduced from the top and flow over substrates before exiting from the bottom of the barrel, while the substrates mounted on the solid susceptor may be rotated around the vertical axis of the susceptor within the barrel. The multi-wafer barrel CVD reactor configuration is a mere extension of the most basic horizontal CVD reactor configuration in which a horizontal CVD reactor is turned through 900 and multiplied around a central axis. Both these reactor configurations are described by Jensen and Kern in Thin Film Processes (II), p. 296-299; J. L. Vossen and W. Kern (eds.), Academic Press, New York, 1991, which is also included herein by reference. The barrel CVD reactor configuration, although useful on small-area substrates, however, is considered inefficient because of the internal gas flow mechanism, which is substantially parallel (longitudinal) to the substrate surface. This flow configuration leads to longer path lengths and thus longer cycle time. It is thus more suitable for CVD type processes. U.S. Pat. No. 5,458,725 describes an arrangement of multiple tubes each with apertures placed parallel to a stationary polygonal susceptor, such that the gas from the tubes is directed in a direction substantially parallel to the stationary susceptor to reduce the particles settling on the substrates attached to the susceptor. U.S. Pat. No. 5,716,484 describes a similar arrangement of multiple vertical tubes, each with a set of apertures on three sides of each tube arranged around a stationary polygonal susceptor. The flow from the tubes impinges on to the stationary susceptor as well as sweeps the inner surface of the barrel to create a swirling flow of gas within the barrel to reduce the particles.

A variety of ALD reactor designs have been introduced to accelerate the overall ALD process by employing multiple and simultaneous processing of substrates in a mini-batch configuration. Kim et al. described an ALD apparatus for simultaneous processing of multiple substrates in U.S. Pat. No. 6,306,216. Recently, multi-wafer continuous-flow ALD reactor configurations with multiple linear injectors for rapid gas distribution on a plurality of wafers rotating around a central axis and being subjected to the gas flow from multiple injectors was described by in U.S. Pat. No. 6,821,563 and U.S. Pat. No. 6,576,062, and also in U.S. Pat. No. 6,634,314. In all these mini-batch ALD reactor configurations multiple substrates are placed on a rotating platform in a horizontal plane that are scanned under linear injectors during rotation. A continuous flow, multi-substrate ALD reactor configuration was described by Bedair et al., for GaAs atomic layer epitaxy process operating at 2.0 micron/h. (˜30 nm/min.) deposition rate who published their results in the Applied Physics Letter, volume 62, No. 19, 10^{th} May 1993. In this ALD reactor configuration, multiple substrates are placed on a susceptor rotating in a horizontal plane and mounted co-axially within a circular chamber which is sub-divided into six equal compartments by quartz partitions. The chamber is supplied with two reactant inlets and an inert gas inlet. The multiple square-shaped substrates mounted on a rotating susceptor are alternatively exposed to the reactants and the inert gas to complete the ALD cycle. Also a multi-wafer ALD reactor configuration with linear injectors mounted above a rotating platen and an atomic layer epitaxial layer process for GaAs thin layers was described by Liu et al., in SPIE volume No. 1676, p. 20 (1992). Use of a laminar flow block comprising multiple linear injectors placed within the outer exhaust port for continuous flow thin film CVD processes in a horizontal conveyer belt configuration is described in the U.S. Pat. No. 5,683,516 and U.S. Pat. No. 6,521,048.

Continuous-flow ALD reactor configurations offer several advantages, such as potentially higher throughput and elimination of complex arrangements of sequencing of gases with fast switching valves. However, the gains that may be realized by multi-wafer ALD reactor configurations can be limited mainly because the reactor volume increases proportionately with the total area of the substrates, thus slowing the overall ALD cycle and the resultant deposition rate. Also, time required to load and unload substrates, which adversely affects the effective throughput, needs to be taken into account. In addition, for batch ALD equipment, the foot-print increases with the number of substrates accommodated, which is yet another factor that requires careful consideration. Furthermore, the substrates such reactors can accommodate are often only planar.

The inherent strengths of an ALD process to offer thin films with low defect density and large area uniformity have been recently applied for fabrication of layers in thin film photovoltaic solar cells. Guillemole et al., reported efficiency of 13.5% in copper indium diselenide (CIGS) solar cells in Japanese Journal of Applied Physics, vol. 40, pp. 6065-6068 (2001); with indium sulfide (In₂Se₃) buffer layers deposited by ALD. Naghavi et al., reported 16.4% efficiency in copper indium diselenide solar cells comprising a 30 nm buffer layer of indium sulfide (In₂Se₃) deposited by ALD; in Progress in Photovoltaics, Research & Development, vol. 11, pp. 437-443 (2003). Ohtake et al., reported deposition of 100 nm thick zinc selenide (ZnSe) buffer layer for copper indium diselenide solar cells by ALD in Japanese Journal of Applied Physics, vol. 34, pp. 5949-5955 (1995) with an operating efficiency of 11%. Very recently, however, application of ALD is being increasingly directed towards fabrication of the main absorber layer with the goal to significantly increase the solar cell efficiency. Johansson et al., described an ALD process to deposit copper sulfide layers employing Cu(thd)₂ [thd: 2,2,6,6,-tetramethyl-3,5,heptanedione) and H₂S as precursors in Journal of Materials Chemistry, vol. 12, pp. 1022-1026 (2002). The rate of deposition at was approx. 0.03 nm/cycle in the temperature range of 125-160 ° C. Recently, Nanu et al., described results of an ALD process to deposit copper indium sulfide (CuInS₂) thin films in Chemical Vapor Deposition, vol. 10, No. 1, pp. 45-49 (2004). The precursors employed for the ALD process were cuprous chloride (CuCl), indium trichloride (InCl₃) and H₂S and the substrates were glass, tin-oxide coated glass and nanoporous TiO₂ coated glass with ALD process temperature in the range of 350-500° C. The rate of film deposition, however, at greater than 8 s/cycle, was rather slow for practical use to deposit about a micron thick absorber layer. Very recently, Roscheisen et al., in US Patent Application No. 2005/0186338 described an ALD apparatus for surface treatment on a flexible substrate that is wound around a hexagonal susceptor in a coil form. In US Patent Application No. 2005/0186342, Sager et al., described an apparatus and ALD process to deposit copper indium gallium selenide (CIGS) absorber layer on a long, flexible substrate coiled around a fixed hexagonal shaped susceptor such that the adjacent turns of the coil do not touch one another. All the gases, reactive and inert, are injected into the ALD chamber through a common inlet at the bottom. The goal of such an ALD system configuration is to massively scale the substrate surface area available to the reactants in an ALD cycle to achieve higher throughput as opposed to taking any measure accelerating the ALD cycle speed on to a smaller substrate. Such an ALD system, however, may have to contend with longer substrate load-unload times, inflexibility with respect to gas injection and substantially longer pulse width leading to longer cycle time—in the range of several minutes. For a solar absorber layer about a micron thick, such a processing system may not entirely suitable.

It is thus clear that an atomic layer chemical vapor processing apparatus that can process large area, flexible substrates at significantly higher cycle speed in an ALD and/or CVD mode and also methods of using the same to process a variety of thin films with high degree of uniformity, precision and control on film thickness and composition during the entire process is highly desired. Unique apparatus and methods to accomplish these ends are taught in enabling detail in this specification.

### SUMMARY OF THE INVENTION

In view of the description of the related art, the present invention describes various configurations of high-speed atomic layer processing apparatus on large area substrates and also methods of operation of such configurations to deposit multi-layer thin films on flexible substrates. The apparatus in the invention in various embodiments is capable of operating at high-speed and within minimum possible foot-print or physical space to uniformly process a substrate or multiple substrates. In the context of this invention, the term atomic layer chemical vapor processing (ALCVP) generally encompasses three processes, namely atomic layer deposition (ALD), atomic layer etching (ALET)—which can be either isotropic or anisotropic, and atomic layer surface modification (ALSM).

Accordingly, the present invention in some embodiments provides an atomic layer chemical vapor processing (ALCVP) reactor that includes a substantially cylindrical chamber with a substantially cylindrical susceptor mounted co-axially within the chamber, thereby defining an annular gap there between. A flexible, rectangular substrate is wrapped on the susceptor so as to cover the circumference of the susceptor. The flexible substrate is in direct thermal contact with the susceptor. The length of the substrate is substantially equal to the circumference of the susceptor, whereas the width of the substrate is substantially equal to the width of the susceptor. The unique ALCVP reactor is further provided in some embodiments with a stationary resistance heater that is mounted underneath the susceptor. Electrical energy to the heater is provided from heater supply power cables that pass through an axially mounted hollow shaft of the susceptor. In one embodiment an open end of the hollow susceptor shaft is encased within another rotary vacuum seal with fixed vacuum feed-through connectors, which establish electrical contact between the heater power supply cables and an external power source. Optionally, longitudinal optical heaters can be mounted on the external chamber walls to transmit radiation on to the substrate through transparent windows installed within the walls of the chamber. In both of these modes of substrate heating, internal and stationary non-contact temperature probes may be mounted within the susceptor cavity to monitor the temperature uniformity of the susceptor and also to control the susceptor temperature in a closed-loop fashion. Connections for non-contact temperature probes may be established through a fixed vacuum feed-though to facilitate closed-loop temperature control. In the embodiments described herein a substrate processing region is adapted to enclose the substrate during processing. A load-unload port opening to the substrate processing region is provided to transfer the substrate in to and out of the substrate processing region. Also a door is provided to load and unload the substrate and to close the load-unload port during processing. Also, the door may be adapted to provide a vacuum seal to the chamber in closed position. The substrate processing region is preferably interposed between the gas injection region and the susceptor that supports the substrate during processing. In this embodiment, the ALCVP reactor comprises at least one composite nozzle mounted within the circular chamber. The composite nozzle is mounted substantially parallel to the axis of rotation of the susceptor on the circumference of the chamber. The composite nozzle comprises one or more inner linear injectors mounted either within or in the vicinity of at least one outer exhaust. Each inner linear injector is provided with a plurality of apertures on one side that direct gas emanating from the apertures towards the substrate. The inner linear injector may be closed at one end with a gas inlet at the opposite end or the inner linear injector may be closed at both ends with a gas inlet in the middle. The inner linear injector is connected to a controlled and metered source of a gas, for example to a mass flow controller. The length of the inner linear injector mounted within the composite nozzle is substantially equal to the width of the susceptor. During the operation of the apparatus, the gas is directed from the inner linear injector towards the substrate so as to cover the width of the substrate while the outer exhaust port simultaneously collects the excess (non-chemisorbed or un-reacted) gas from the surface of the substrate. While the gas is being flown from the inner linear injector and simultaneously being collected through the outer exhaust port of the composite nozzle, the susceptor is rotated around its axis to ensure sequential coverage of the substrate by the gases. It is well-known that the gas flow on a rotating cylinder is deflected in the direction of rotation, to compensate for such a deflection, the alignment of the gas flow with respect to the susceptor surface (angle made by the direction of the gas flow from the inner linear injector with respect normal to the susceptor surface) can be changed by simply tilting the inner linear injector. The outer exhaust port of the composite injector is connected to a gate valve which in turn is connected to a throttle valve. The throttle valve is connected to a vacuum source e.g., a vacuum pump through a reactive gas/chemical vapor collection trap to collect the unused chemical precursor/gas injected into the ALCVP reactor.

In a preferred embodiment, the ALCVP reactor is provided with four composite nozzles mounted on the circumference of the chamber and substantially parallel to the axis of the chamber. The composite nozzles are positioned in the sequence such that the angular separation between the two adjacent composite nozzles is substantially same. Also, the chamber is provided with four rectangular flow partitioning plates extending in radial direction inward from the circumference of the chamber. Each flow partitioning plate is positioned in the space between two adjacent composite nozzles along the circumference of the chamber. Moreover, each flow partitioning plate is mounted on the bellows so that separation between its lower edge and the substrate surface can be adjusted as desired. During the operation of the ALCVP reactor, a first composite nozzle injects a first reactive gas A and also simultaneously collects excess or non-chemisorbed gas A from the substrate surface. A second composite nozzle injects an inert gas P on to the substrate to sweep off and collect non-chemisorbed (excess) reactive gas A along with the inert gas P from the substrate. A third composite nozzle injects a second reactive gas B and also collects non-chemisorbed second reactive gas B from the substrate. A fourth composite nozzle injects the inert gas P on to the substrate and simultaneously collects the reaction by-products of the atomic layer processing reaction between the first reactive gas A and the second reactive gas B in addition to the inert gas P. Continuous rotation of the substrate attached to the co-axially mounted susceptor while the four composite nozzles continuously operate subjects the substrate surface sequentially to a gaseous reaction process comprising the first reactive gas A, the inert gas P, the second reactive gas B and the inert gas P thereby completing one atomic layer chemical vapor processing sequence. Processing of the thin film of desired thickness is achieved by rotating the substrate through pre-determined number of rotations. The exhaust ports of the first and second composite injectors are connected to a common pipe which is connected to a first gate valve. The first gate valve is connected to a first throttle valve which is in turn connected to a vacuum pump through a first chemical condensation/collection trap. Similarly, the exhaust ports from the third and fourth composite injectors are connected to a common pipe which is connected to a second gate valve. The second gate valve is connected to a second throttle valve which is in turn connected to the vacuum pump through a second chemical condensation/collection trap.

In another embodiment, the ALCVP reactor is provided with four composite nozzles wherein the first composite nozzle and the third composite nozzle each comprise at least two inner linear injectors and each inner linear injector is connected to a distinct, controlled and metered reactive gas supply. The composite nozzles are positioned in the sequence such that the angular separation between the two adjacent composite nozzles is substantially same. The ALCVP reactor is also provided with four rectangular flow partitioning plates. The reactive gases being supplied to any one of the composite nozzles are selected such that do not react spontaneously with each other within the composite nozzle. However, these reactive gases collectively exhibit reactivity towards the reactive gases being supplied to the other composite nozzle. In this embodiment of the ALCVP reactor, the first composite nozzle employs first reactive gas A and third reactive gas C; the second composite nozzle employs the inert gas P; third composite nozzle employs reactive a second reactive gas B and the fourth reactive gas D and the fourth composite nozzle employs an inert gas P. In this particular configuration of the ALCVP reactor, first atomic layer chemical vapor processing sequence comprising the first reactive gas A, an inert gas P, the second reactive gas B and the inert gas P (for example: A, B, P and P) is carried out initially by rotating the susceptor to sequentially expose the substrate to all the required composite nozzles set in operation. The first atomic layer chemical vapor processing sequence is followed by a second atomic layer processing sequence comprising the third reactive gas C, inert gas P, the fourth reactive gas D and inert gas P, (for example: C, P, D and P) without removing the substrate from the ALCVP reactor. Alternatively, a thin film of variable composition comprising elements derived from all the reactive gases A, B, C and D can be processed. Also, composition of the film can be varied in-situ during processing by simply properly adjusting (or switching off, if desired) flows of one or more reactive gases selected from the group comprising A, B, C and D. Furthermore, an alternating double layer structure comprising (AB)ₘ-(CD)ₙ-(AB)ₒ-(CD)ₚ . . . (here, m, n, o and p are all integers ) can be processed by suitably switching the flows of the reactive gases A, B, C and D on and off while rotating the substrate though pre-determined number of rotations.

In yet another embodiment the ALCVP reactor is provided with four composite nozzles and four rectangular flow partitioning plates. The composite nozzles are positioned in the sequence such that the angular separation between the two adjacent composite nozzles is substantially same. The inner linear injector of the first composite nozzle is connected to the distinct and independently controlled supplies of reactive gases denoted by symbols A₁, A₂, and A₃. The inner linear injector of the second composite nozzle is connected to an inert gas P. The inner linear injector of the third composite nozzle is connected to the distinct and independently controlled supplies of reactive gases denoted by symbols B₁, B₂, and B₃. The reactive gases of first group A₁, A₂ and A₃ are selected such that they do not react with each other spontaneously. So also the reactive gases of second group B₁, B₂ and B₃ do not react with each other spontaneously. However, the reactive gases of the first group exhibit high reactivity towards the reactive gases of second group which is highly desirable to perform ALCVP type of processes. In this embodiment of the ALCVP reactor, a thin film of composition comprising all six elements A₁, A₂, A₃, B₁, B₂, and B₃ can be processed with varying degree of relative concentrations of all six elements.

In another embodiment the ALCVP reactor is provided with six composite nozzles, including two composite nozzles supplying inert gas, mounted substantially parallel to the chamber axis within a circular chamber. The ALCVP reactor is also provided with four flow partitioning plates.

In an alternative embodiment of the ALCVP reactor the cross section of the susceptor is a polygon, preferably an octagon with each face shaped as a trapezoid, mounted co-axially within a substantially circular atomic layer processing chamber. Furthermore, each trapezoid shaped face of the susceptor has provision to hold at least one substrate. Except for the geometry of the susceptor, the details of configuration of the ALCVP reactor are similar to those described in the preferred embodiment. During the operation of the ALCVP reactor, the susceptor with multiple individual substrates mounted on it, is rotated around its axis while the reactive and inert gases are flown from all the composite nozzles to ensure complete coverage of the substrates by the gases in a desired sequence. Processing of thin film of desired thickness is achieved by pre-determined number of rotations. Also, each face of the trapezoidal susceptor makes an acute angle with respect to the vertical axis of the chamber in order to facilitate holding of the substrate during susceptor rotation. For an inclined susceptor configuration, all the composite nozzles are also mounted inclined substantially at the same angle with respect to vertical, and thus substantially parallel to the surface of the susceptor.

In yet another embodiment of the present invention, at least two cylindrical shaped susceptors are mounted within a rectangular shaped chamber. A flexible metallic belt is employed as a substrate holder which is in direct thermal contact with the susceptor. At least one flexible substrate is mounted on the substrate holder. Each cylindrical susceptor is further provided with a stationary heater mounted concentrically underneath. Additionally, two longitudinal stationary heaters are provided within the space defined by the two cylindrical shaped susceptors to heat the substrate. Four composite nozzles are mounted on the periphery of the rectangular chamber and in the vicinity of the susceptor such that during the operation of the apparatus the inner linear injector, each having a plurality of apertures along one side and mounted within the composite nozzles, directs the gas towards the substrate to substantially cover the substrate width. Simultaneously the outer exhaust port of the composite nozzle collects the excess gas in the vicinity of the substrate subsequent to its impingement on the substrate while the substrate attached to the flexible metallic belt is set in motion by rotating at least one of the cylinders. The sequence of installation of four composite nozzles is first reactive gas A, inert gas P, second reactive gas B and inert gas P in the direction of the rotation of the substrate. The desired atomic layer chemical vapor processing sequence is performed by rotating the substrates while all the composite nozzles are operational. Alternatively, in this particular embodiment of the ALCVP reactor, the flexible metallic belt may be entirely replaced by a flexible substrate which can be in the form of a sleeve that can be directly rolled on to the cylindrical shaped susceptors. The desired film thickness can be processed by simply rotating the substrate through pre-determined number of rotations.

In configurations of the ALCVP reactor as described above the flexible substrate can be rolled and fitted onto the susceptor with a pair of ceramic end connectors that fit on to the susceptor. Also, the substrate may be mounted on the susceptor in the form of a sleeve. Alternatively the substrate can be held in position on to the susceptor by employing vacuum suction or an electrostatic chuck, or may be mounted in a recessed cavity. In the case of a polygonal susceptor, the substrate may be held in a recess in an inclined position on a facet of the polygonal susceptor. Additionally pins may be employed to hold the substrate in position. The substrate material is selected from, but is not limited to, metal-coated plastic, stainless steel, aluminum, molybdenum or suitable alloys of other metals, silicon, compound semiconductors e.g., silicon carbide, gallium arsenide, gallium nitride wafers, quartz or soda glass may be suitable substrate materials.

Accordingly, various configurations of a flexible substrate processing described herein are employed to process thin films of precisely controlled composition wherein the film composition can be dynamically changed in-situ through the film thickness as desired which is useful in the fabrication of graded band gap solar cells; multi-junction thin film solar cells; large area catalytic coatings with precisely tailored composition, precision interface engineering and multi-layer thin film optical coatings on large area substrates among a variety of other applications. Moreover substrate processing may be achieved at a significantly higher speed in atomic layer processing mode or at a significantly higher rate in chemical vapor processing mode. The rate of thin film processing in atomic layer mode largely depends-on the rate of rotation of the susceptor. The rate of thin film processing in high rate mode depends on rate of susceptor rotation, rate of reactive gas flows towards the substrate and the substrate temperature. Thus, the configurations of the apparatus of the present invention significantly accelerate the process of atomic layer processing on large-area flexible substrates, and also on multiple substrates within a small volume and small foot-print. The ALCVP apparatus of this invention in many embodiments is oriented such that the axis of rotation of the susceptor is parallel to the ground plane. However, it is important to note that since the substrate is wrapped and held on to the susceptor, any other suitable orientations of the axis of susceptor rotation will be equally effective for the operation of the apparatus. Operation of the apparatus and chemical processes for deposition of multi-layer, graded and multi-component thin film materials for photovoltaic solar cells and other applications are described in detail below with the help of various drawings.

### BRIEF DESCRIPTION OF THE DRAWINGS

FIG. 1 is a schematic of a multi-wafer barrel CVD reactor a related art, used for thin film deposition on multiple substrates.

FIG. 2A is a cross sectional schematic view of a multi-substrate, rotating platen ALD reactor with four tube injectors, a related art.

FIG. 2B is a top schematic view of a multi-substrate, rotating platen ALD reactor as shown in FIG. 2A, illustrating an arrangement of tube injectors with respect to substrates.

FIG. 3A is a schematic cross section of a parallel linear injector slots system employed for chemical vapor deposition of thin films on a row of heated substrates traversing underneath on a conveyer belt—related art.

FIG. 3B is the schematic cross sectional view of an ALD system employing a set of closely spaced, multiple and alternating parallel injectors to inject reactive gas A, inert gas P and reactive gas B, each connected to a common exhaust employed for thin film atomic layer deposition to complete an ALD the sequence of A, P, B and P—a related art.

FIG. 4A is a two-dimensional view of a generic stagnation point flow configuration developed by orthogonal impingement of an axially uniform jet on a flat surface, as described in related art, to develop a uniform boundary layer of thickness=δ and with a stagnation point of the flow P formed at the center of the jet.

FIG. 4B is a two-dimensional view of a generic stagnation point flow configuration developed by impingement of a round jet on a cylindrical surface, as described in prior art, to develop a uniform boundary layer of thickness=δ′ and with a stagnation point of the flow P′ formed at the center of the jet.

FIG. 5A is a schematic cross sectional view along the length of a composite nozzle comprising one inner linear injector and an outer exhaust port.

FIG. 5B is a bottom view of the exit port of the composite nozzle as shown in FIG. 5A illustrating an inner linear injector arranged within an outer exhaust port.

FIG. 6A is schematic cross sectional view across the width of a composite nozzle comprising two inner linear injectors arranged side-by-side within an outer exhaust port.

FIG. 6B is a bottom view of the exit port of the composite nozzle as shown in FIG. 6A illustrating two inner linear injectors arranged side-by-side within a common outer exhaust port.

FIG. 7 is the bottom view of an alternate composite injector with an inner linear injector with a side inlet and two parallel outer linear exhaust ports.

FIG. 8 is the bottom view of yet another configuration of a composite injector with an inner linear injector having an inlet in the middle and two exhaust ports at the opposite ends of the inner linear injector.

FIG. 9A-9D are bottom views illustrating four different arrangements of outlet ports of an inner linear injector.

FIG. 10 are the flow profiles that can be developed by employing various outlet ports, either singularly or in combination with one another, of the inner linear injector. L is the length of the outlet port of the inner linear injector as shown in FIG. 9A-9D.

FIG. 11A is the schematic arrangement of a flow partitioning plate mounted at the end of a bellow on the wall of the ALCVP reactor showing stepper motor and gear arrangement for precision movement of the flow partitioning plate.

FIG. 11B is the schematic arrangement of a flow partitioning plate mounted within a lip seal with a pair of O-rings on the wall of the ALCVP reactor showing stepper motor and gear arrangement for precision movement of the flow partitioning plate. FIG. 12A is the pictorial view of a flexible substrate with width=w, length=L and thickness=t; having an upper and lower surfaces.

FIG. 12B is the top view of the assembly of the flexible substrate with ceramic end connectors attached to the opposite ends of the substrates.

FIG. 12C is the side view of the flexible substrate with ceramic end connectors attached to the opposite ends illustrating recesses in the ceramic end connectors to pick and place the substrate—ceramic end connector assembly. Inset shows a magnified view of the ceramic end connector assembly employed to hold the flexible substrate.

FIG. 13 is the cross sectional view of a circular susceptor with two adjacent longitudinal and parallel grooves for placement of ceramic end connectors attached to the substrate.

FIG. 14 is the schematic illustration of the first step in attachment of the flexible substrate in which the first ceramic end connector is placed firmly in the first groove and subsequently the susceptor is rotated in anti-clockwise direction.

FIG. 15 is the schematic illustration of the final step of attachment of the flexible substrate in which second ceramic end connector attached to the opposite end of the substrate (along the width) is firmly placed in the second groove and thereby the substrate is wrapped and held around the susceptor.

FIG. 16 is a schematic vertical cross sectional view of the preferred embodiment of an atomic layer processing reactor with four composite nozzles, in x-z plane, with a first composite nozzle connected to a controlled supply of a first reactive gas A, a second composite nozzle connected to a controlled supply of an inert gas P; a third composite nozzle connected a controlled supply of a second reactive gas B and a fourth composite nozzle connected to a controlled supply of an inert gas P and all sequentially arranged within a circular atomic layer processing chamber and a flexible substrate attached to a co-axially mounted cylindrical susceptor.

FIG. 17 is a schematic vertical cross sectional view of an atomic layer processing reactor, as shown FIG. 16, with controlled sources of reactive gases A₁, A₂ and A₃ connected to the first composite nozzle and controlled sources of reactive gases B₁, B₂ and B₃ connected to the third composite nozzle.

FIG. 18 is a schematic vertical cross sectional view of an atomic layer processing reactor with six composite nozzles, in x-z plane, with a first composite nozzle connected to controlled supply of a first reactive gas A, a second composite nozzle connected to a controlled supply of an inert gas P; a third composite nozzle connected a controlled supply of a second reactive gas B; the fourth composite nozzle connected to a controlled supply of an inert gas P; a fifth composite nozzle connected to a controlled supply of a third reactive gas C and a sixth composite nozzle connected to a controlled supply of a controlled supply of a fourth reactive gas D.

FIG. 19 is a horizontal schematic cross sectional view of the ALCVP reactor of FIG. 16 in x-y plane showing the placement of the substrate, non-contact temperature sensors mounted within an internal cavity, rotary vacuum seals on both ends with a motor and pulley arrangement for susceptor rotation.

FIG. 20 is a schematic vertical cross sectional view of an alternate embodiment of an atomic layer processing reactor with four composite nozzles, in x-z plane, with a first composite nozzle connected to a controlled supply of a first reactive gas A, a second composite nozzle connected to a controlled supply of an inert gas P; a third composite nozzle connected a controlled supply of a second reactive gas B and a fourth composite nozzle connected to a controlled supply of an inert gas P and all sequentially arranged within a circular atomic layer processing chamber; a co-axially mounted susceptor with polygonal cross section and planar substrates attached to the facets of the susceptor.

FIG. 21 is a horizontal schematic cross sectional view of the ALCVP reactor of FIG. 20 in x-y plane showing the placement of the substrate, non-contact temperature sensors mounted within an internal cavity, rotary vacuum seals on both ends with a motor and pulley arrangement for susceptor rotation.

FIG. 22 illustrates a schematic cross section of an alternate configuration of the atomic layer chemical vapor processing reactor with four sequentially arranged composite nozzles mounted within a rectangular cross section atomic layer chemical vapor processing chamber and with flexible substrates mounted on a metal belt that rolls over the two heated cylindrical susceptors.

FIG. 23 is a schematic of the atomic layer chemical vapor processing system comprising the atomic layer chemical vapor processing reactor of this invention, chemical precursor metering and supply system for each of the composite nozzles, a gate valve, a throttle valve and a filter cum trap set for the reactive gas A and a similar set of gate valve, throttle valve and filter cum tram for the reactive gas B and a vacuum pump. The ALCVP reactor control system is not shown in the diagram.

FIG. 24A is an illustration of the schematic cross section of a first susceptor configuration with a recess employed to hold the planar substrate during rotation.

FIG. 24B is an illustration of the schematic cross section of a second configuration of the susceptor employing a vacuum outlet to hold the planar substrate during rotation.

FIG. 24C is an illustration of the schematic cross section of a third configuration of a susceptor, employing active elements of electrostatic-chuck, to hold the planar substrate during rotation.

FIG. 24D is an illustration of the schematic cross section of a fourth configuration of a susceptor, employing circumferential recess on the susceptor to mount a flexible substrate on to the susceptor.

FIG. 25A shows the schematic view of placement of a single flexible substrate on a cylindrical susceptor.

FIG. 25B shows the schematic view of placement of multiple flexible substrates on the cylindrical susceptor.

FIG. 25C shows the schematic view of placement of a single planar substrate on the facet of an octagonal susceptor.

FIG. 25D shows the schematic view of placement of multiple planar substrates on the facet of the octagonal susceptor.

### DETAILED DESCRIPTION OF THE INVENTION

The present invention relates to thin film processing—including at least deposition, etching and surface modification at a single atomic layer precision for a number of applications, including manufacturing of semiconductor devices, photovoltaic solar cells, displays and thin films, on large area flexible and planar substrates for applications such as catalytic electrodes, membranes and panels and so forth. The following descriptions are of various embodiments of the invention, and various modifications to the embodiments described will be apparent to those skilled in the art, and the patentable subject matter described and claimed herein may be applied to other embodiments. Thus the present invention is not intended to be limited to the embodiments shown but is to be accorded the widest scope consistent with the principles and various features described herein.

The present invention provides atomic layer chemical vapor processing (ALCVP) apparatus configurations that can achieve coverage of flexible and also multiple planar substrates by reactive gases in a compact volume, small foot-print with flow stability and in a very short path length. In various embodiments a combination of rapid, repetitive and relative motion of a substrate with various gas injection schemes in the form of a steady flow of projecting gas jets achieves rapid and substantially complete surface coverage. It should thus be clearly apparent to an individual skilled in the art that such an apparatus is generic in nature and thus not limited by the reaction chemistry of the desired process to be performed on the substrate, for example, but not limited to, synthesis of a film, removal of the substrate material (etching) or modification of the chemical nature of the substrate. Hence, apar5atus in embodiments of the invention have a secondary purpose to process, using one or more embodiments described herein, a variety of thin films of metals, semiconductors and insulators and suitable combinations thereof with atomic level precision on one or more substrates under suitable process conditions. Furthermore, it should be noted that the operational range of processes for atomic layer chemical vapor processing is sufficiently wide with respect to operating parameters including, but not limited to, operating chamber pressure, gas flow rates and substrate temperature. Suitable operating pressure range can be from slightly below 760 Torr to a few hundred milli-Torr, whereas the reaction temperature is dependent upon particular vapor phase reaction chemistry. It is highly advisable in most cases to operate processes at minimum gas flow rates. However, the flow rates must be adequate to supply a sufficient quantity of reactive species to the substrate surface in order to obtain substantially complete, and if required, uniform surface coverage. To an individual skilled in the art adaptation of such a methodology of optimization of process parameters and also the tools required to achieve the same (for example mass flow controller, temperature controller, pressure controller, valve controls and closed loop control of the process parameters etc.), to control the process variables and to develop a desired process recipe is well-known.

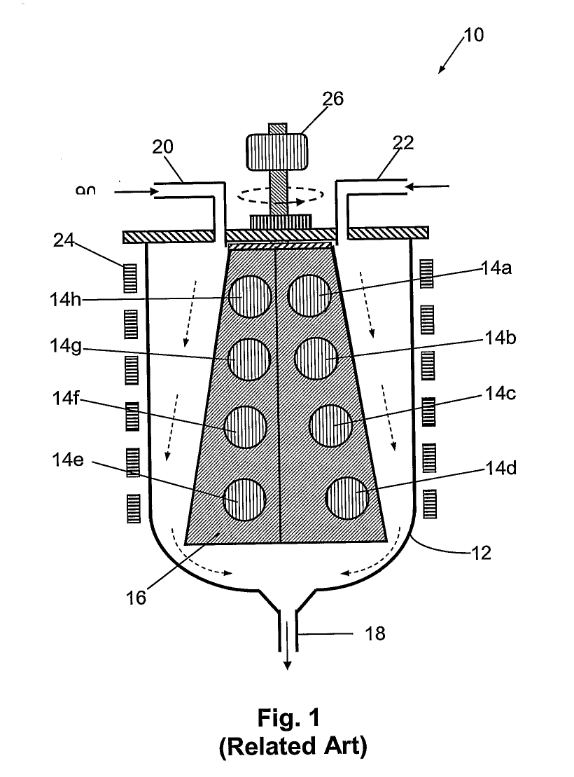

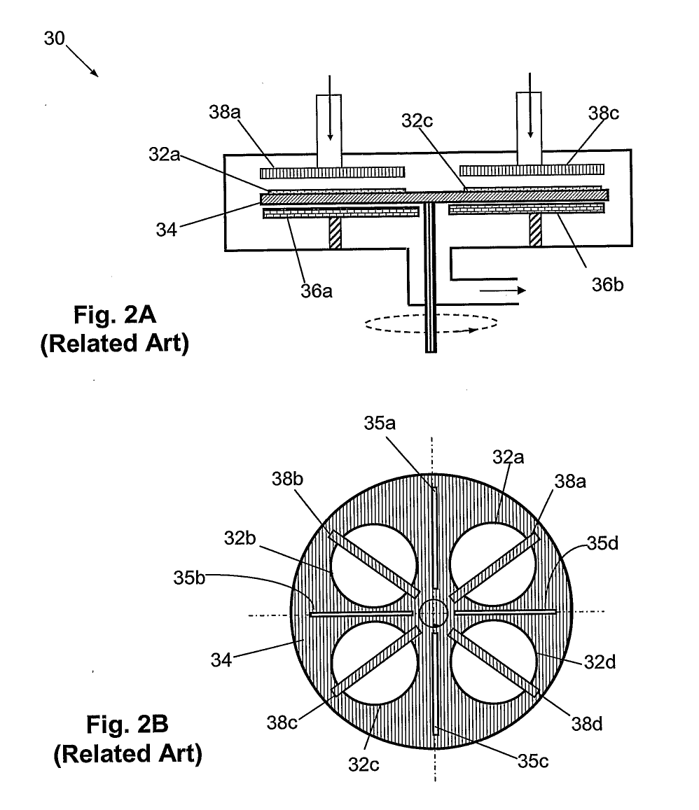

The invention in several embodiments, including various apparatus designs and their operation, is described in detail in this section with the help of various schematic diagrams starting with existing apparatus as known to the inventor. A schematic of a multi-wafer, barrel-type CVD reactor system 10, in practice prior to the present invention, as an example of related art is shown in FIG. 1. An outer cylindrical barrel 12 constitutes a chamber in which substrates 14a, 14b, . . . 14g and 14h are placed on facets of a solid hexagonal cross section susceptor 16 in recessed regions on the facets of the susceptor 16. The susceptor 16, with a number of substrates 14a, 14b, . . . 14g and 14h attached to it, is placed in a cylindrical barrel 12 with an outlet 18 at the bottom connected to a vacuum pump (not shown in the diagram). The reactive gases necessary for vapor phase deposition reaction are supplied from inlets 20 and 22 respectively at the top. Susceptor 16, heated by external heating arrangement 24, is rotated around its vertical axis by an external rotation mechanism 26. An ensuing chemical vapor deposition reaction on the surface of the heated substrates deposits a desired thin film. Large volume barrel CVD reactors, though simple in operation, are not suitable for reactive chemistries wherein the precursor gases tend to react spontaneously upon mixing as is the case in ALD processes. FIG. 2A is a schematic vertical cross section of a multi-wafer ALD reactor 30 employed to deposit thin films on four substrate wafers 32a, 32b, 32c and 32d placed on a horizontal susceptor 34 heated by fixed heaters 36a and 36b respectively that are placed underneath the susceptor 34. While the reactive gases flow continuously through the injector tubes 38a and 38c, and the inert gases flow continuously through the injector tubes 38b and 38d fixed at the top (injector tubes 38b and 38d are not shown in FIG. 2A), the susceptor is continuously rotated around its vertical axis in a horizontal plane. All the wafers are alternately exposed to reactive gases and inert gases to complete an ALD process sequence consisting of four types of gases in a repetitive manner to build the desired film thickness. FIG. 2B is the top view of the multi-wafer ALD reactor as shown in FIG. 2A showing relative positions of injector tubes with respect to the substrate wafers and the susceptor. FIG. 2B also illustrates fixed flow partitioning plates 35a, 35b, 35c and 35d that are inserted vertically downward (perpendicular to the susceptor plane) in the gap between the two adjacent injector tubes. The flow partitioning plates help break the stagnant boundary layer that begins to develop on the substrates under steady flow of gas from the injector tubes and helps facilitate rapid transport of chemical specie from the next injector to the substrate surface.

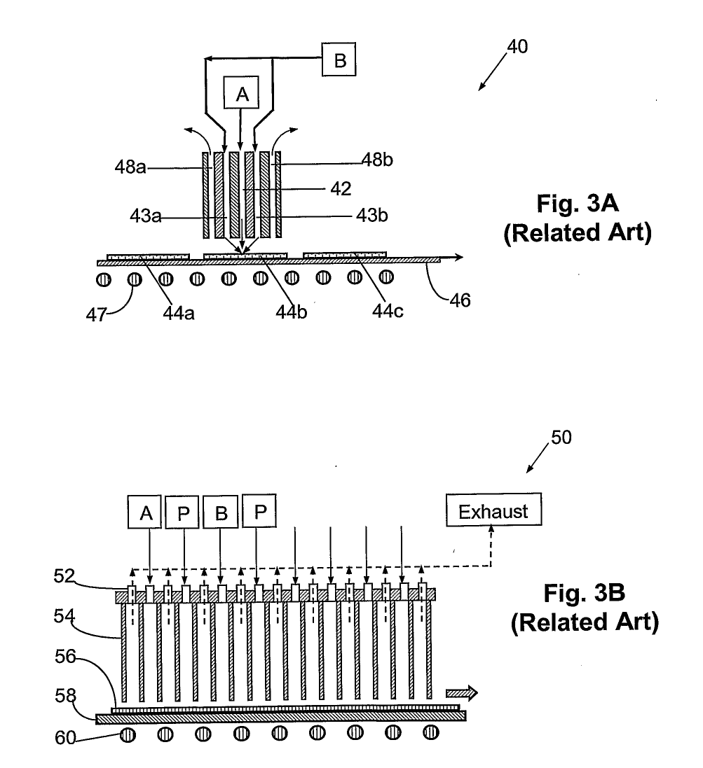

FIG. 3A is a schematic cross sectional view of a parallel linear injector slots CVD system 40, employed for deposition of thin dielectric films on heated substrates traversing underneath in a straight line on a conveyer belt. A first precursor A is injected through an inner slot 42 and simultaneously a second precursor B is injected from two adjacent slots 43a and 43b placed on both sides of inner slot 42. The gas flow from the three parallel slots 42, 43a and 43b impinges downwards on a row of substrates 44a, 44b, 44c . . . as the substrates are successively exposed to the reactive gases by a moving conveyer belt 46. The substrates are heated by a set of fixed tubular heaters 47 placed underneath the conveyer belt 46. The reaction gases exit from the outer, parallel exhaust slots 48a and 48b.

FIG. 3B is a schematic cross sectional view of an ALD system 50, employing multiple sets of alternating and closely spaced parallel injectors and vacuum ports 52. In this configuration, each gas injector, either for a reactive gas or for an inert gas, is separated by a vacuum port. A set of injectors and vacuum ports 52 is connected to a set of parallel slots 54 to transport reactive and inert gases to the surface of the substrate 56 underneath and also from the substrate 56 to the common vacuum port above. All the injectors are fed from respective gas sources while all the vacuum ports, interposed between two gas inlets, are connected to a common exhaust manifold. The substrate 56, placed on a susceptor 58 and heated by a stationary heater 60 mounted underneath, traverses in one direction.

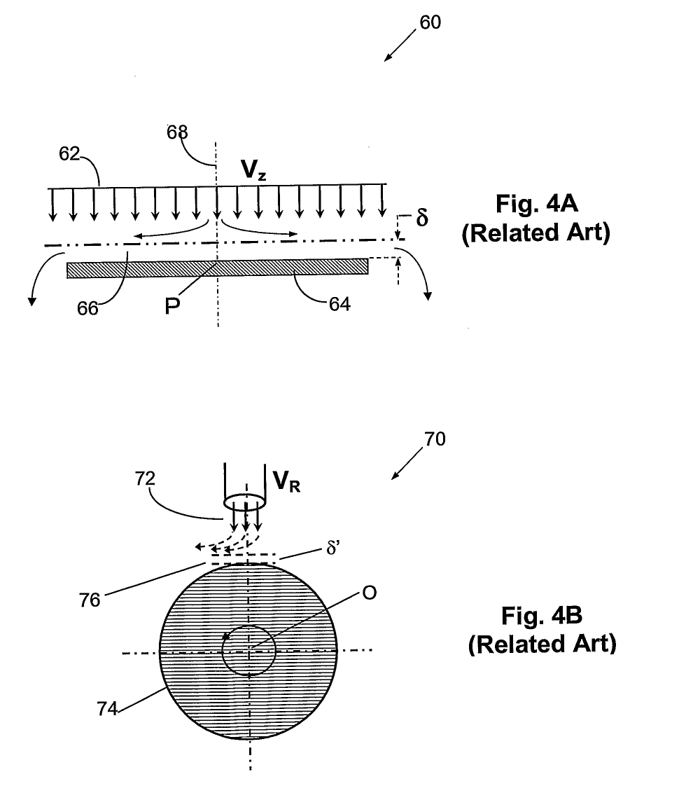

FIG. 4A is the schematic illustration of a two-dimensional stagnation-point fluid-flow configuration 60 in related art, distinguished by impingement of a flat jet 62 with uniform axial velocity V_{z} onto a flat solid surface 64 at right angle. The ensuing fluid flow configuration develops a substantially uniform boundary layer 66 of thickness=δ and a stagnation point at the center of the jet indicated by letter P. Solid arrows show the direction of fluid flow in the vicinity of the solid surface 64.

FIG. 4B is the schematic illustration of a basic two dimensional stagnation-point fluid-flow configuration 70 in related art, distinguished by impingement of a jet 72 with exit velocity=V_{R} on to a curved cylinder 74 rotating around its axis in a counterclockwise direction. A boundary layer 76 of thickness=δ with a stagnation point P′ is developed on the surface of the cylinder 74 at the center of the jet 72. Arrows show the direction of fluid flow in the vicinity of the surface of a rotating cylinder 74 such that the flow is induced or deflected (pulled) in a direction of rotation of the cylinder.

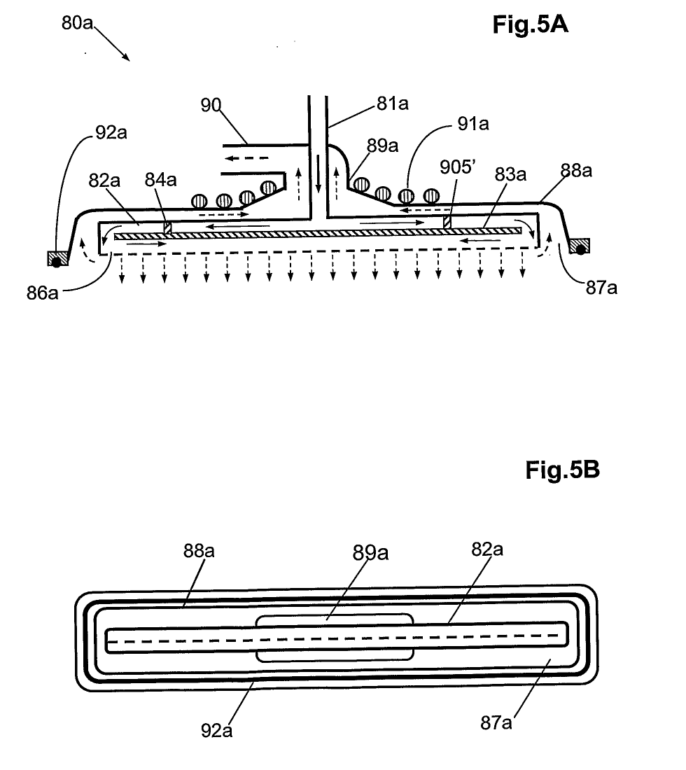

FIG. 5A is a schematic cross sectional view along the length of a composite nozzle 80a comprising an inlet tube 81a, in an embodiment of the present invention. The inlet tube 81a is connected to a first inner linear injector 82a. The inner linear injector 82a is a hollow cavity that is closed at both ends with gas inlet 81a in the middle and a perforated gas outlet on one side for directional gas ejection. Alternatively, the inner linear injector 82a can be a hollow cavity closed at one end with a gas inlet 81a at the opposite end. A flow diverting plate 83a is mounted within the inner linear injector 82a with the help of two mounting screws 84a and 85a. The inner linear injector 82a has an opening plate 86a with a plurality of apertures for gas injection (described further below in more detail). The inner linear injector 82a is enclosed within an outer exhaust port 87a formed by an enclosure 88a. The enclosure 88a is connected to an exhaust cone 89a and the exhaust cone 89a is connected to an outlet tube 90 for connection to a vacuum system. Also, the composite nozzle 80a is provided with an external heater 91a in order to prevent condensation of the exhaust gases. Finally, the composite nozzle 80a is provided with a peripheral O-ring seal 92a to obtain a vacuum seal to a chamber body.

FIG. 5B is a bottom view of the composite nozzle 80a of FIG. 5A with one inner linear injector 82a having an opening plate 86a with plurality of apertures, mounted within an enclosure 88a forming an outer exhaust port 87a. The outer exhaust port 87a is connected to the exhaust cone 89a. The peripheral O-ring seal 92a is employed to provide a vacuum seal.

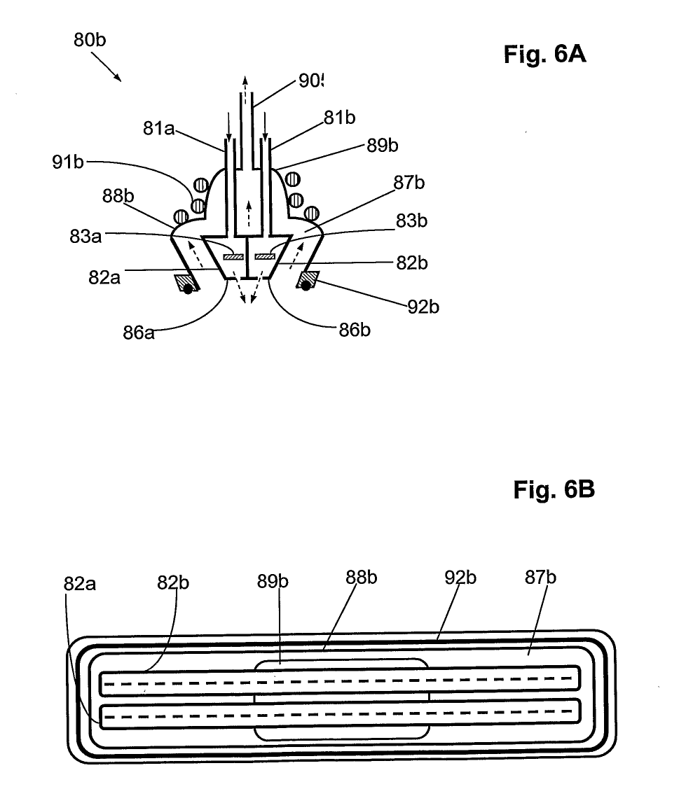

FIG. 6A is a schematic cross sectional view along the width of a composite nozzle 80b in an embodiment of the invention comprising two inlet tubes 81a and 81b mounted in close proximity to each other. The first inlet tube 81a is connected to a first inner linear injector 82a and the second inlet tube is connected to a second linear injector 82b. Flow diverting plates 83a and 83b are mounted within the inner linear injectors 82a and 82b respectively. Inner linear injector 82a has an opening plate 86 a with plurality of apertures for gas injection and the inner linear injector 82b has an opening plate 86b with plurality of apertures for gas injection. Details of aperture plate patterns are described in further detail below. The inner linear injectors 82a and 82b are enclosed within an outer exhaust port 87b formed by an enclosure 88b. The enclosure 88b is connected to an exhaust cone 89b and the exhaust cone 89b is connected to an outlet tube 90 for connection to the vacuum system (not shown in the diagram). Also, the composite nozzle 80b is provided with an external heater 91b in order to prevent condensation of the flow of exhaust gases. Moreover, the composite nozzle 80b is provided with a peripheral O-ring seal 92b to provide a vacuum seal to the chamber body during processing, details of which are described below. It should be noted that the inner linear injectors 82a and 82b respectively can both be replaced by tubes with both ends closed and with a gas inlet in the middle and having plurality of apertures on one side for directional gas injection or with two tubes with one end closed and the gas inlet provided at the opposite end or a suitable combination thereof. It should also be noted that the use of flow diverting plates for the composite nozzle configurations as described in FIGS. 5A and 6A is optional. However, as will be described later, for some process chemistries, such as those involving active plasma where an active plasma source is directly connected to the inlet tubes 81a and 81b, inclusion of flow diverting plates 83a and 83b within the composite nozzles 80 and 80′ may be beneficial to minimize impact of highly energetic and at times detrimental active species in the plasma on the substrate.

FIG. 6B shows the bottom of the composite nozzle 80b as described in FIG. 6A with two inner linear injectors 82a and 82b having opening plates 86a and 86b each with plurality of apertures, mounted within in an enclosure 88b forming an outer exhaust port 87b. The outer exhaust port 87b is connected to a exhaust cone 89b. A peripheral O-ring seal 92b is provided to help obtain vacuum seal.

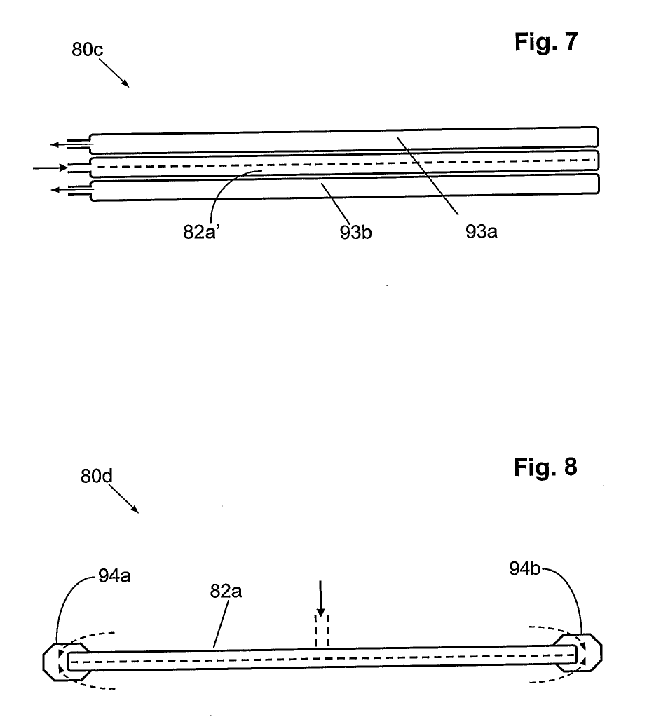

FIG. 7 shows a bottom view of an alternate configuration of a composite nozzle 80 c in which an inner linear injector 82a′ with an inlet at one end and opposite end closed and with a plurality of apertures on one side is flanked on both sides by two exhaust ports 93a and 93b such that flow emanating from the apertures of the inner linear injector 82a′, subsequent to impingement on the substrate is absorbed by the exhaust ports 93a and 93b.

FIG. 8 shows the bottom view of yet another configuration of a composite nozzle 80d with an inner linear injector 82a. The inner linear injector 82a has both ends closed with an inlet in the middle, the configuration is as described in detail in FIG. 6A, is provided with two exhaust ports 94a and 94b placed at both ends of the inner linear injector 82a.

It should be noted here that the inner inlet tubes 81a and 81b in the composite nozzle as shown in FIGS. 6A and 6B may be connected to a controlled supply of two different reactive gases that do not react with each other spontaneously. The outlet tube 90 of all the composite nozzle configurations, 80a through 80d described in detail herein and shown in FIGS. 5A, 5B, 6A, 6B, 7 and 8, may be connected to a source of vacuum, e.g., a pump through an arrangement of a gate valve, a throttle valve and a filter/trap which will be described in detail later. The flow paths for gases within all the composite nozzle configurations 80a through 80d are described by solid arrows for the incoming flow and by broken arrows for the outgoing flow.

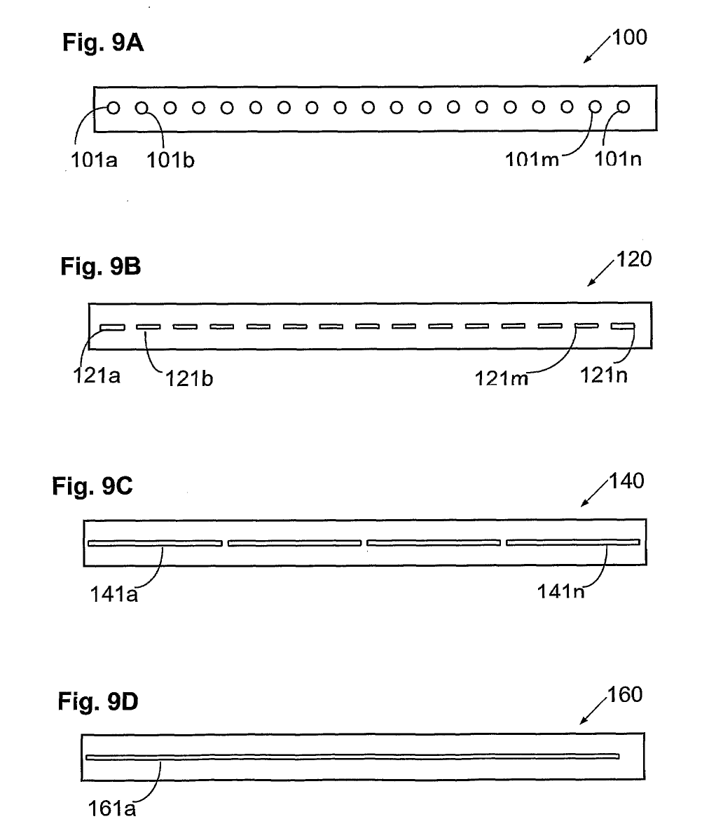

FIG. 9A is a bottom view of a hole pattern 100 for opening plates 86a and 86b with a plurality of circular shaped outlets 101a, 101b, . . . . 101m and 101n. FIG. 9B is a bottom view of a hole pattern 120 for the opening plates 86a and 86b with a plurality of slots 121a, 121b, . . . . 121m and 121n. FIG. 9C shows a bottom view of a hole pattern 140 for the opening plates 86a and 86b with a plurality of longer slots 141a, 141b . . . 141m and 141n. FIG. 9D is a bottom view of a hole pattern 160 for the opening plates 86a and 86b with a one longitudinal slot 161a. To an individual skilled in the art it is understood that an aperture pattern of the opening plate 86a and 86b can be by a suitable combination of various patterns shown in FIGS. 9A-9D and also within a particular aperture pattern, the dimensions and spacing of a particular feature such as hole diameter, slot width and length and its relative spacing can vary as may be required for a particular chemical process.

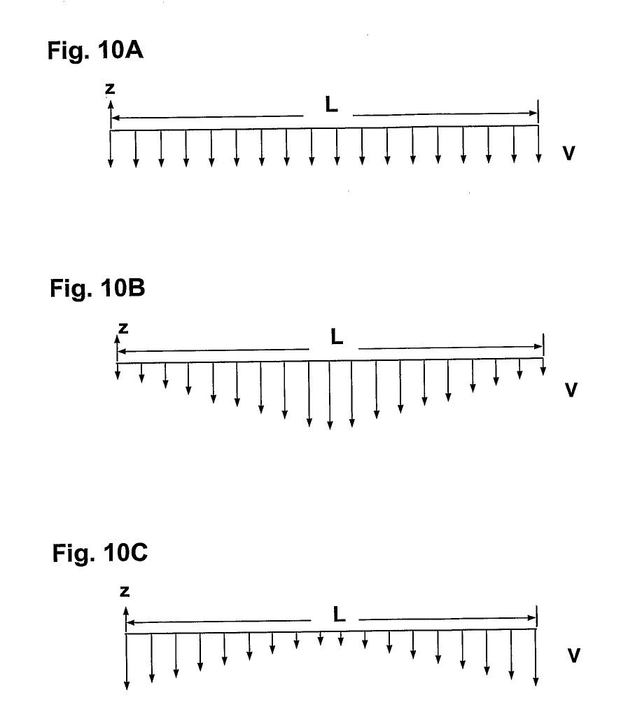

FIGS. 10A-10C illustrate three different profiles of velocity distribution of gas flow along the length of an inner linear injector of length L. It should be noted here, and will be apparent to an individual skilled in the art, that various other velocity distribution profiles are achievable with a combination of various linear injector configurations and shapes and sizes and inlet tube placements under various operating conditions of inlet flow rate and operating pressure. Furthermore, it should be noted that the inner linear injector can be replaced by an in-situ chemical vapor generator as described in the U.S. patent application Ser. No. 10/975,169 filed Oct. 27, 2004 by the inventor. This entire patent application is included herein by reference.

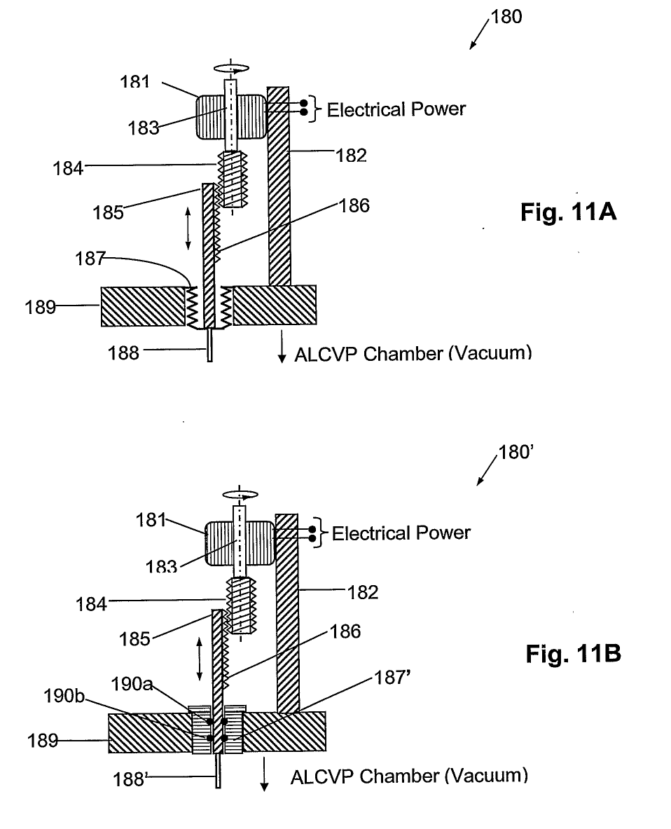

FIG. 11A is a schematic cross sectional view of a moveable, internal flow partitioning plate sub-system 180 employing a stepper motor 181 mounted on a support bridge 182. The rotor 183 is provided with radial gear threads 184. An external plate 185 is also provided with planar gear threads 186 that are met with the radial gear threads 184. The external plate 185 is connected to bellows 187. The bellows 187 may be connected to an ALCVP chamber body 189 and are also connected to the moveable, internal flow partitioning plate 188. Precision rotation of the radial gear threads 184 met with planar gear threads 186 attached to the external plate 185 allows precision positioning of the moveable, internal flow partitioning plate 188 inside the ALCVP chamber during processing as desired.

FIG. 11B is a cross sectional view of an alternate arrangement of a moveable, internal flow partitioning plate sub-system 180′ that employs a pair of O-rings 190a and 190b respectively within a lip-seal 187′ to produce a vacuum seal to an ALCVP chamber body 189. The lip-seal 187′ also holds the external plate 185 to affect precision positioning of the moveable, internal flow partitioning plate 188′ within the ALCVP chamber.

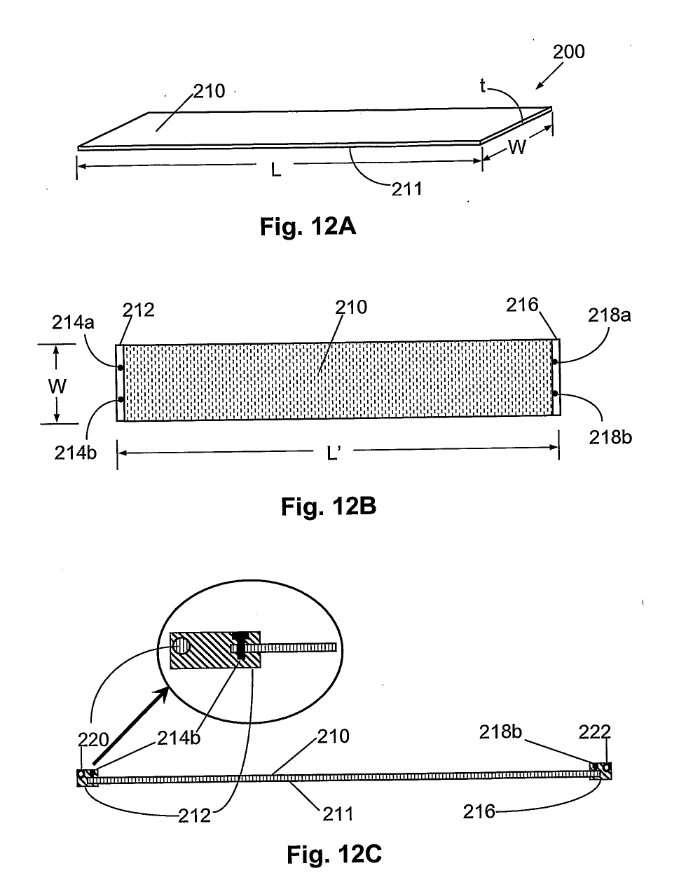

FIG. 12A shows a perspective view of a flexible substrate 200 with length=L; width=w and thickness=t. The substrate 200 is further characterized by an outer surface 210 and an inner surface 211.

FIG. 12B shows a top view of the substrate 200 (with its outer surface 210) with a first ceramic end connector 212 attached at one edge (along the width w) with a first pair of end connector screws 214a and 214b respectively and a second ceramic end connector 216 attached to the opposite parallel edge with a second pair of end connector screws 218a and 218b respectively. The total length of the assembly (including the 2×width of each ceramic end connector is=L′ such that L′>L).

FIG. 12C shows a side view of the flexible substrate 200, with its outer substrate surface 210 and inner substrate surface 211, held by ceramic end connectors 212 and 216 respectively attached at the opposite ends. A first end connector recess 220 and a second connector recess 222 are provided to assist in mechanized pick-and-place (for example with the help of a robotic fork) arrangement to handle the substrate, details of which are described below. An enlarged view of the first ceramic end connector 212 in the inset shows the position of the first end connector recess 220 and end connector screw 214b.

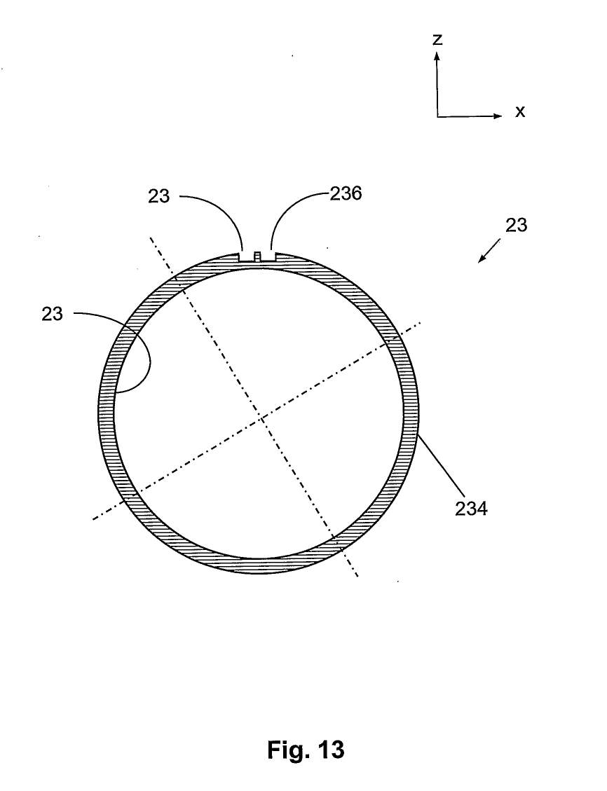

FIG. 13 shows a cross section of a circular susceptor 230 in an embodiment of the invention. The circular susceptor 230 is further characterized by an inner susceptor surface 232 and an outer susceptor surface 234. The circular susceptor 230 is also provided with a first locking slot 236 and a second locking slot 238 along its width. As described above, the width of the substrate is substantially equal to the width of the susceptor. Moreover the dimensions of the first locking slot 236 and the second locking slot 238 are comparable to the dimensions of the first ceramic end connector 212 and the second ceramic end connector 216.

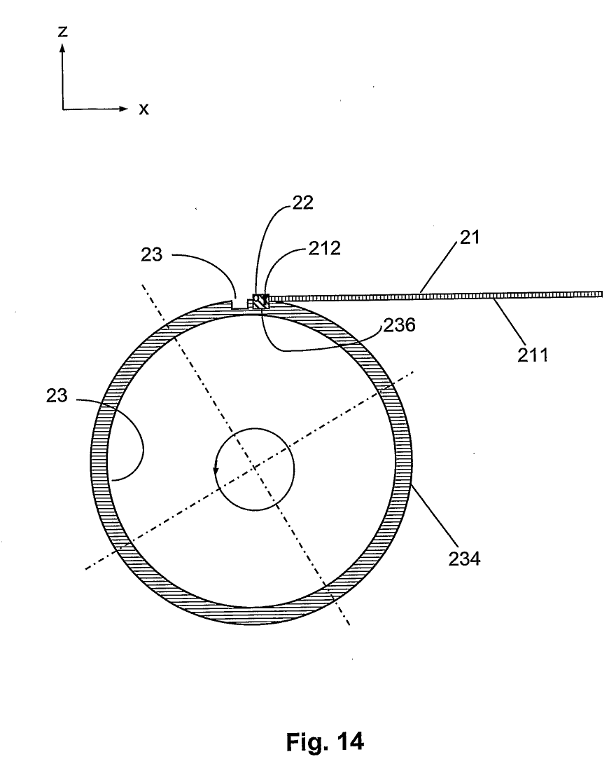

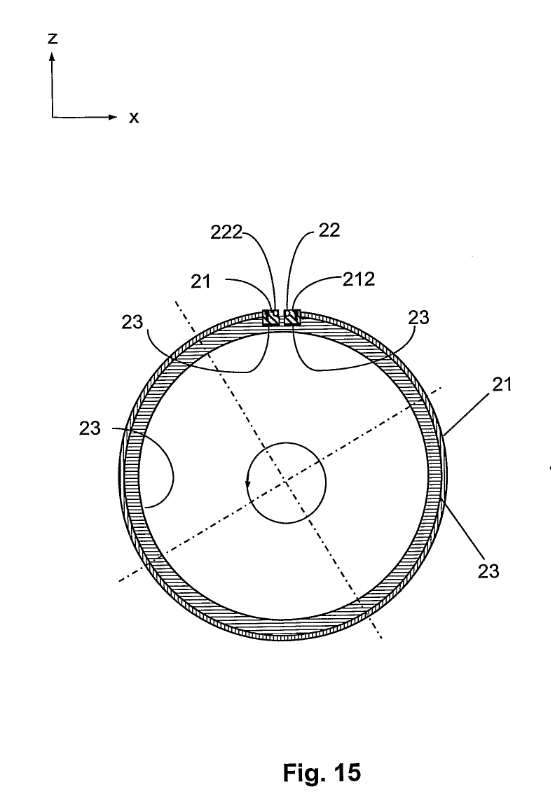

FIG. 14 illustrates a first step in the process of placement of the flexible substrate 200 on to the circular susceptor 230. Herein, the substrate 200, with both the ceramic end connectors 212 and 216 respectively attached to the opposite ends, is carried by a mechanized fork arrangement (not shown in the diagram) by inserting the fork ends in to the first end connector recess 220. In a second step, the first ceramic end connector 212 is firmly placed in to the first locking slot 236. In a third step, the susceptor 230 is rotated in counterclockwise direction in this example to wrap the substrate 200 onto the outer susceptor surface such that the inner substrate surface 211 is in firm mechanical contact with the outer susceptor surface 234 and the outer substrate surface 210 is exposed. Finally, the second ceramic end connector 216 is firmly placed in to the second locking slot 238 and the process of mounting (wrapping) a flexible substrate on to a susceptor is completed as shown in FIG. 15.

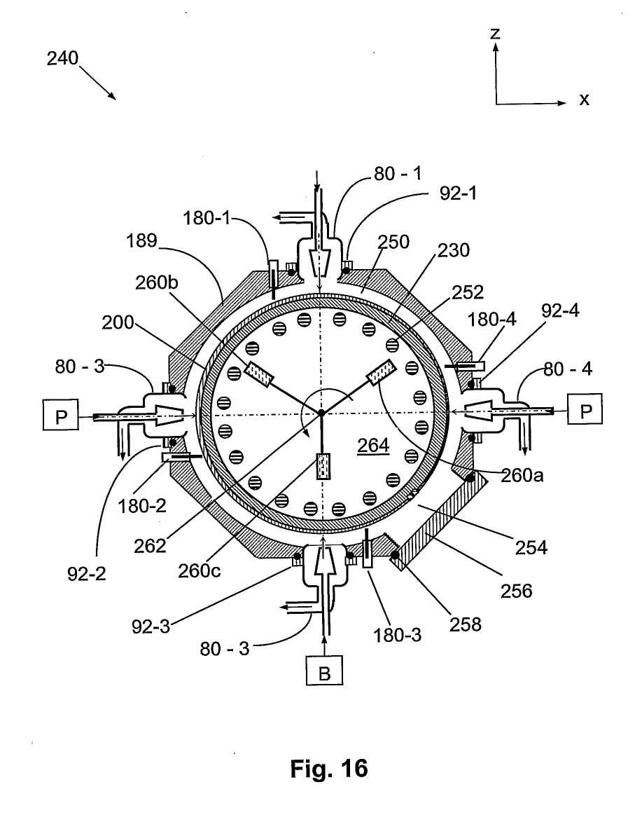

FIG. 16 is a schematic vertical cross sectional view of an atomic layer chemical vapor processing (ALCVP) reactor 240, in z-x plane, according to a preferred embodiment of the present invention. It is to be noted that the axis of rotation of all the ALCVP reactor configurations, as described herein, is parallel to the ground plane, but this is not a limitation, as the axis may be in another orientation. The atomic layer processing reactor 240 is a small volume, compact and short path length atomic layer chemical vapor processing reactor which comprises a chamber body 189 that is substantially cylindrical in shape. The chamber body 189 in this embodiment is further provided with four composite nozzles 80-1, 80-2, 80-3, and 80-4 respectively, serially mounted on the circumference of the chamber body 189 such that the angular distance between the two adjacent composite nozzles is substantially the same and the nozzles are equally spaced around the periphery of the body. It is made explicitly clear herein, for the sake of simplicity of nomenclature, that although the invention describes four types of composite nozzles namely 80a (shown schematically in FIGS. 5A-5B), 80b (shown schematically in FIGS. 6A-6B), 80c (shown schematically in FIG. 7) and 80c (shown schematically in FIG. 8) hereafter all four composite nozzles are referred by a single numeral 80 and the hyphenated suffixes 1, 2, 3 and 4 are used to refer to the first, second, third and fourth composite nozzle respectively. Thus, each of the four nozzles may be selected from the group comprising composite nozzles 80a, 80b, 80c and 80d. Further, in this configuration of the ALCVP reactor, a controlled supply of a first reactive gas A is connected to the first composite nozzle 80-1; a controlled supply of an inert gas P is connected to the second composite nozzle 80-2; a controlled supply of a second reactive gas B is connected to the third composite nozzle 80-3; and a controlled supply of an inert gas P is connected to the fourth composite nozzle 80-4. The exhaust outlets of each of the four composite nozzles 80-1, 80-2, 80-3, and 80-4 respectively are connected to a vacuum source (not shown in the diagram). It is emphasized here that the details of mass flow control mechanism for the supply of respective gases are not shown in the diagram. However, to an individual reasonably skilled in the art, these are well understood. The composite nozzles 80-1, 80-2, 80-3, and 80-4 are attached to the chamber body 189 with the help of O-ring seals 92-1, 92-2, 92-3 and 92-4 respectively. A circular susceptor 230 with a stationary backside heater 252 is co-axially mounted within the chamber body 189 so as to define an annular gap 250 there between. A flexible substrate 200 is wrapped onto the circular susceptor 230. The ALCVP reactor 240 is provided with a substrate load-unload port 254 and a door 256 with an O-ring seal 258. The door 256 can be operated by a remotely controlled pneumatic valve arrangement (not shown in the diagram), to close and open the substrate load-unload port 254. The door 256 in closed position provides a vacuum seal to the chamber body 189 during substrate processing. Furthermore, the ALCVP reactor 240 is provided with fixed non-contact temperature measurement probes 260a, 260b and 260c to monitor the temperature of the inner susceptor surface 232 and thereby to control the electrical energy supplied to the stationary backside heater 252 in a closed loop fashion. Although the details of closed-loop temperature control circuitry and associated hardware is not shown in the diagram, to an individual reasonably skilled in the art these are well known. The axis of rotation of the susceptor is denoted by numeral 262. During substrate processing, while all the composite nozzles 80-1, 80-2, 80-3, and 80-4 operate, the circular susceptor 230 maintained at a desirable temperature is rotated in this example in counterclockwise direction around the axis of rotation 262 to process a thin film of desired dimensions through a predetermined number of susceptor rotations. Subsequent to completion of a desired number of substrate rotations, the flows of reactive gases may be switched off and the substrate may be cooled in the flow of inert gases. Details of ALCVP reactor operation are provided below. Moreover, at least one of the composite nozzles employing reactive gases namely 80-1, and 80-3, can be in the form of an in-situ chemical vapor precursor generator as disclosed in the U.S. patent application Ser. No. 10/975,169; filed Oct. 27, 2004; which is incorporated herein in its entirety by reference. Finally, details of the exhaust port arrangements from adjacent composite nozzles and their connectivity scheme are described below.

In another embodiment the ALCVP reactor 240, the configuration of the first composite nozzle 80-1 and the third composite nozzle 80-3 is as shown in FIGS. 6A-6B while the configuration of the second composite nozzle 80-2 and fourth composite nozzle 80-4 is as shown in FIGS. 5A-5B. It is to be noted herein that chemical precursors employed in the adjacent inner injectors 82a and 82b respectively of the first composite nozzle 80-1 and also the chemical precursors being employed the third composite nozzle 80-3 are selected such that they do not react with each other within a particular composite nozzle. However, together they tend to react with both the chemical precursors being employed from the other composite nozzle. The remaining details of the configuration of the ALCVP reactor of the second embodiment are similar to those described for the embodiment of the ALCVP reactor 240 as shown in FIG. 16.

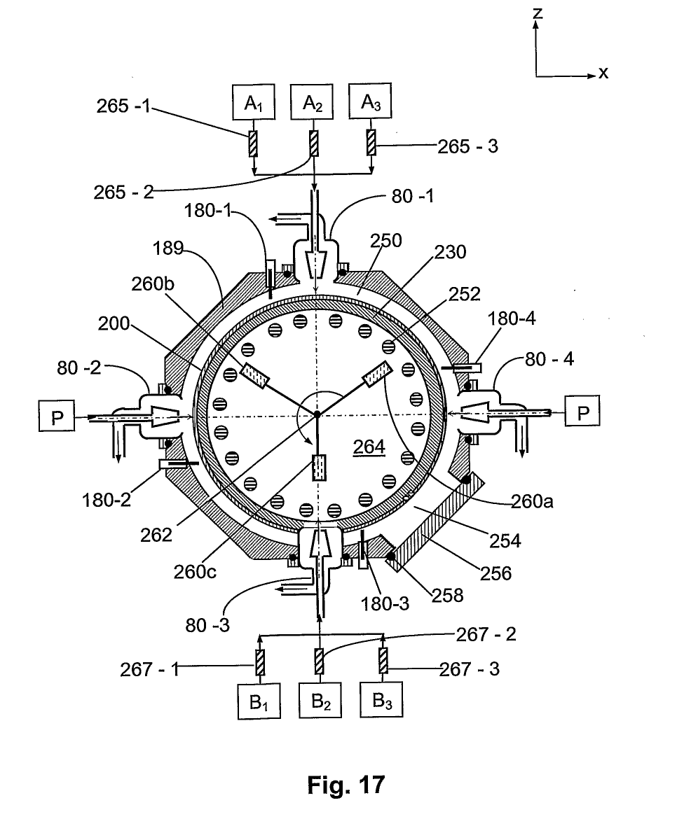

FIG. 17 illustrates a schematic vertical cross sectional view of the atomic layer chemical vapor processing (ALCVP) reactor, in z-x plane, in a third embodiment of the invention, with four composite nozzles mounted on the circumference of the chamber body 189 such that the angular distance between the two adjacent nozzles is substantially the same. The first composite nozzle 80-1 is connected to a controlled supply of three distinct reactive gases A₁, A₂ and A₃ through mass flow controllers 265-1, 265-2 and 265-3 respectively. The three reactive gases A₁, A₂ and A₃ are selected such that they do not react with each other spontaneously. Similarly, the third composite nozzle 80-3 is connected to a controlled supply of three distinct reactive gases B₁, B₂ and B₃ through the mass flow controllers 267-1, 267-2 and 267-3 respectively. The three reactive gases B₁, B₂ and B₃ are selected such that they do not react with each other spontaneously. However, together B₁, B₂ and B₃ tend to react with all of A₁, A₂ and A₃ spontaneously. The remaining details of ALCVP reactor configuration shown in FIG. 17 are exactly same as described above for FIG. 16.

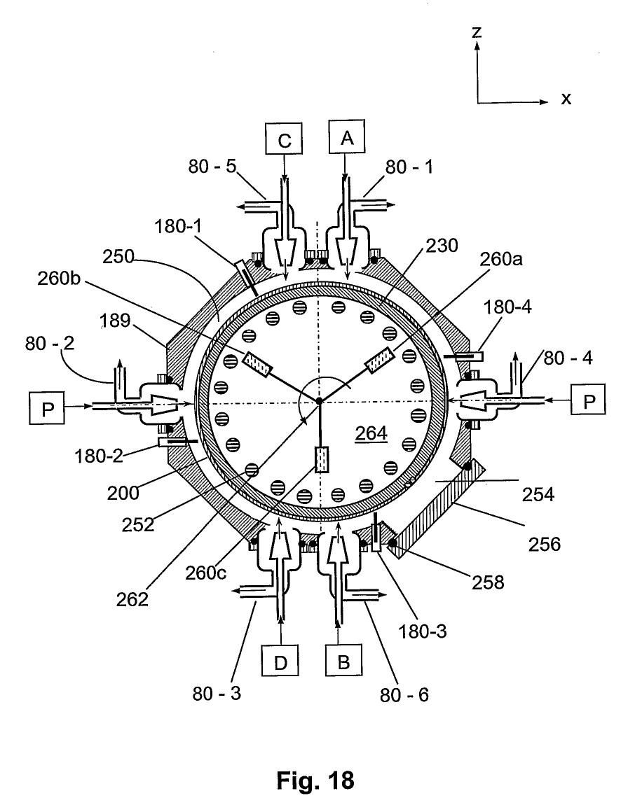

FIG. 18 illustrates a schematic vertical cross sectional view of an atomic layer chemical vapor processing (ALCVP) reactor 240, in z-x plane, according to a fourth embodiment of the present invention. In this embodiment of an ALCVP reactor, the first composite nozzle 80-1 employing the first reactive gas A and fifth composite nozzle 80-5 employing a third reactive gas C are mounted in close proximity to each other while the composite nozzle 80-3 employing the second reactive gas B and the sixth composite nozzle 80-6 employing a sixth reactive gas D are mounted in close proximity to each other and substantially diametrically opposite to the pair consisting of the first composite nozzle 80-1 and the fifth composite nozzle 80-5 employing the reactive gases A and C respectively. The composite nozzle 80-2 and the composite nozzle 80-4 both employing an inert gas P are mounted substantially midway between the pairs of composite nozzles employing reactive gases. In this embodiment, a first atomic layer chemical vapor processing sequence comprising the first reactive gas A, an inert gas P, the second reactive gas B and the inert gas P is carried out by rotating the susceptor to sequentially expose the substrate to the gas flow from the composite nozzles 80-1, 80-2, 80-3 and 80-4 set in operation. The first atomic layer chemical vapor processing sequence is followed by a second atomic layer processing sequence comprising the third reactive gas C (from the fifth composite nozzle 80-5), inert gas P (from the second composite nozzle 80-2), fourth reactive gas D (from the sixth composite nozzle 80-6) and inert gas P (from the fourth composite nozzle 80-4), without removing the substrate from the ALCVP reactor. Alternatively, a thin film of variable composition comprising any desired composition of the elements, comprising metals, non-metals etc., derived from the reactive gases A, B, C and D can be processed. Furthermore, composition of either or both films can be varied in-situ during processing by simply properly adjusting (or switching off completely, if required) flows of one or more reactive gases A, B, C and D. Thus a multi-component thin film with a variable composition or compositional gradient through thickness or double layer or a multi-layer (in this particular case an alternating double layer film with structure (AB)ₘ-(CD)ₙ-(AB)ₒ-(CD)ₚ . . . (here, m, n, o and p are integers) can be processed by rotating the susceptor through desired number of rotations.

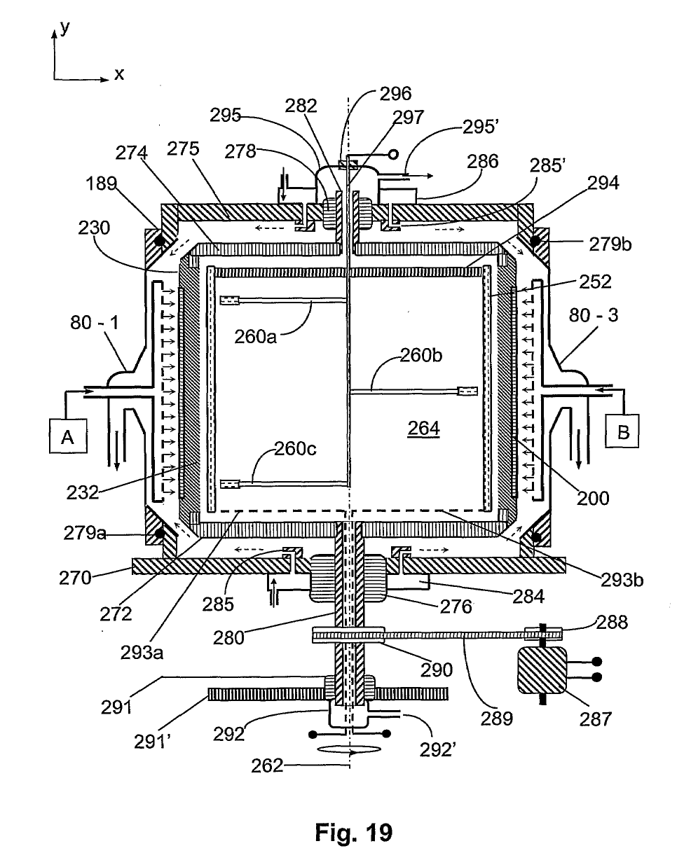

FIG. 19 is a cross sectional view, in x-y plane, of the ALCVP reactor as shown in FIG. 16. FIG. 19 shows the chamber body 189 with co-axially mounted circular susceptor 230 installed on a base plate 270 and first composite nozzle 80-1 and third composite nozzle 80-3 mounted diametrically opposite each other and substantially parallel to the axis of rotation of the susceptor 262. The circular susceptor 230 is supported in this embodiment by a lower susceptor holder plate 272 and enclosed by an upper susceptor holder plate 274 to define a cavity 264. The ALCVP reactor is further provided with a lower rotating seal 276 mounted within the base plate 270 and an upper rotating seal 278 mounted within the cap plate 275. The cap plate 275 and the base plate 270 are connected to the chamber body 189 with the help of O-ring seals 279a and 279b respectively. A lower hollow shaft 280 passes through the lower rotary seal 276 and connects to the lower susceptor holder plate 272. The upper hollow shaft 282 passes through the upper rotary seal 278 and connects to the upper susceptor holder plate 274. The circular susceptor 230 held in place by the lower susceptor plate 272 and the upper susceptor holder plate 274 is thus mounted co-axially within the chamber body 189 and is free to rotate around its axis of rotation 262. A lower purge cavity 284, concentrically placed around the lower rotary seal 276, is provided with circumferential inlets 285 to introduce a purge gas (direction of gas flow shown by broken arrows) in order to assist functioning of the composite nozzles 80-1 and 80-3. An upper purge cavity 286, concentrically placed around the upper rotary seal 278 is provided with circumferential inlets 285′ to introduce a purge gas that flows towards the composite nozzles 80-1 and 80-3. For susceptor rotation, an electric motor 287 is provided in vicinity of the lower rotary shaft 280. A driving pulley 288 is connected to the electric motor 287. A belt 289 connects the driving pulley to the driven pulley 290 mounted on to the lower hollow shaft 280. The lower hollow shaft 280 is placed inside a base rotary seal 291. The base rotary seal 291 is connected to a first fixed support plate 291′. A susceptor purge gas cavity 292 is attached to the base rotary seal 291 to encase the lower hollow shaft 280. A susceptor purge inlet 292′ is provided to the susceptor purge gas cavity 292 to introduce a purge gas within the cavity 264. Electrical power supply leads 293a and 203b pass through the lower hollow shaft 280 and also through the base rotary seal 291 to an external heater electrical power supply (not shown in the diagram). Within the cavity 264, the stationary backside heater 252 is supported and fixed in position with respect to the rotating circular susceptor 230 with the help of a heater support plate 294. The upper hollow shaft 282, placed within the upper rotary seal 278, is enclosed in an upper susceptor purge gas cavity 295. A vacuum feed-through 296 is provided to the upper susceptor purge gas cavity 295 to place a support and contact rod 297 in to the cavity 264 and also to hold the non-contact temperature sensors 260a, 260b and 260c that sense (measure and close-loop control) the temperature of the inner susceptor surface 232 during substrate processing. The details of close-loop temperature control system for the susceptor temperature control are not shown in the diagram. However, to an individual reasonably skilled in the art, such an arrangement is known. Finally, it is made clear herein that the upper susceptor purge gas cavity 295 is connected to a second fixed support plate (hot shown in the diagram), similar to the fixed ground support plate 291′, to hold the ALCVP reactor 240 in place firmly.

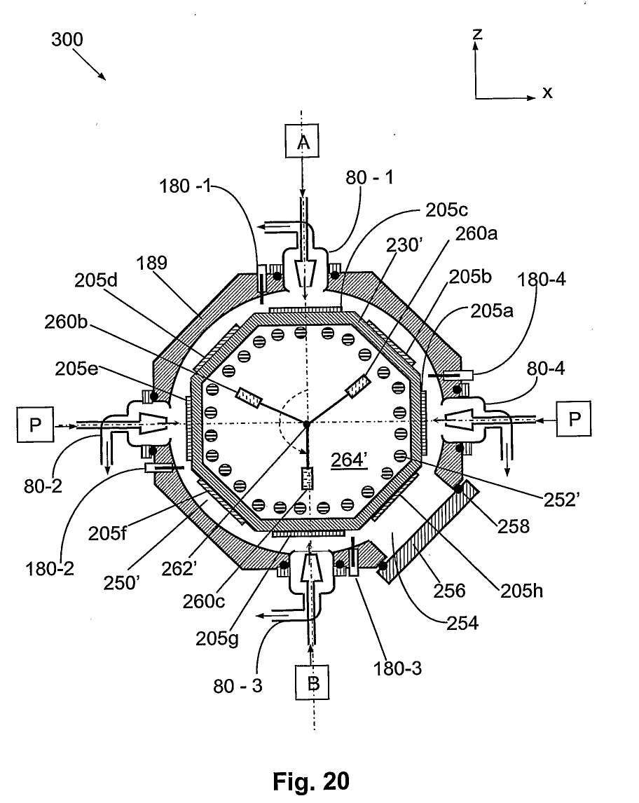

FIG. 20 is a schematic vertical cross sectional view of an atomic layer chemical vapor processing (ALCVP) reactor 300, in z-x plane, according to an alternative embodiment of the present invention. Reactor 300 comprises four composite nozzles, in x-z plane, with a first composite nozzle 80-1 connected to a controlled supply of a first reactive gas A, a second composite nozzle 80-2 connected to a controlled supply of an inert gas P; a third composite nozzle 80-3 connected a controlled supply of a second reactive gas B and a fourth composite nozzle 80-4 connected to a controlled supply of an inert gas P and all sequentially arranged within a circular atomic layer processing chamber such that the angular distance between two adjacent composite nozzles is substantially the same. A co-axially mounted octagonal susceptor 230′ within the chamber body 189 defines a gap 250′ there between. A stationary backside octagonal cross section heater 252′ is mounted within the susceptor cavity 264′. Eight planar substrates 205a, 205b, 205c, 205d, 205e, 205f, 205g and 205h are attached to the eight faces of the octagonal susceptor 230′ in operation in this embodiment.

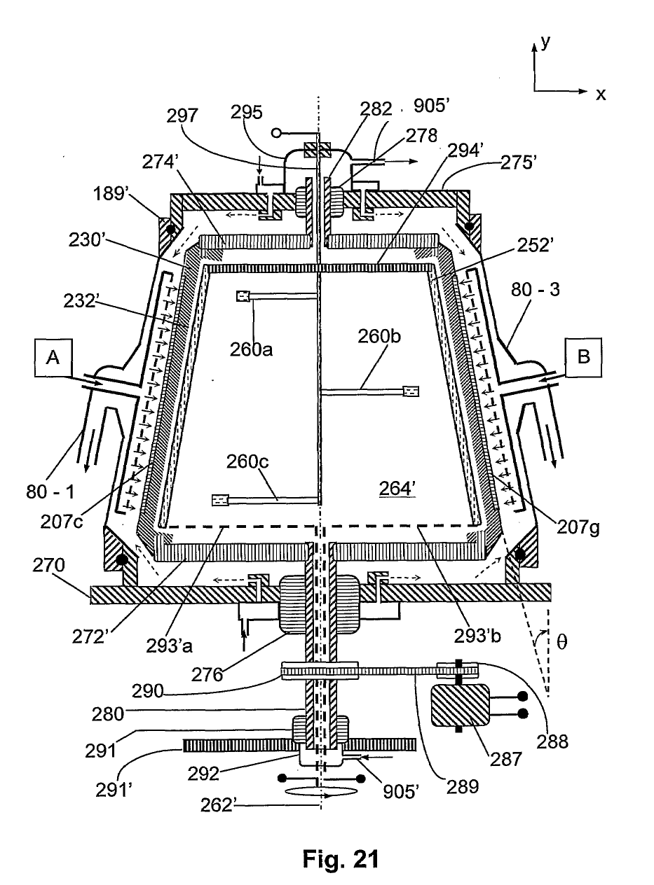

FIG. 21 is a horizontal cross sectional view, in x-y plane, of the alternative embodiment of the ALCVP reactor 300 shown in FIG. 20. The plane or facet of an octagonal susceptor 230′ makes an acute angle θ (such that 0°≦θ≦15°) with respect to vertical. All the composite nozzles (only 80-1 and 80-3 are shown in the diagram) are mounted substantially parallel to the susceptor surface 230′. So also the stationary backside heater 252′ is mounted in an inclined position with respect to the octagonal susceptor 230′ such that the lateral distance between the backside of the susceptor 232′ and the stationary backside heater 252′ is substantially same. The remaining details of the configuration of the ALCVP reactor of the alternate embodiment shown in FIG. 21 are similar to those described for the preferred embodiment of the ALCVP reactor as shown in FIG. 19.

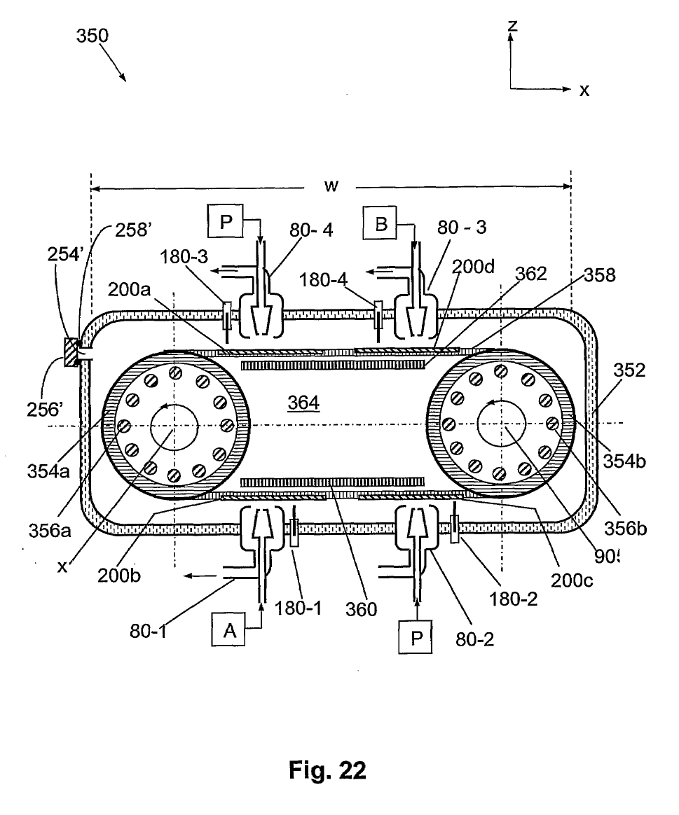

FIG. 22 illustrates yet another embodiment of an ALCVP reactor 350 employing a rectangular ALCVP chamber 352. A first rotating susceptor 354a with its axis of rotation at x and a second rotating susceptor 354b with its axis of rotation at x′ are mounted within the rectangular ALCVP chamber 352 such that the line joining x-x′ is substantially parallel to one of the walls (denoted by letter w) of the chamber 352. The first rotating susceptor 354a connected to an external rotary mechanism (not shown in the diagram) is a driving susceptor whereas the second rotating susceptor 354b is a driven susceptor. The first rotating susceptor 354a is provided with a first stationary internal heater 356a and the second rotating susceptor 354b is provided with a second stationary internal heater 356b. A flexible metallic belt 358 connects the first rotating susceptor 354a with the second rotating susceptor 354a. The flexible metallic belt 358 has provisions to hold a plurality of flexible substrates 200a, 200b, 200c and 200d. The ALCVP reactor 350 is further provided with two fixed and flat heaters 360 and 362 respectively mounted within the cavity 364 between the two rotating susceptors 354a and 354b respectively. The ALCVP chamber 350 is provided with four composite nozzles 80-1, 80-2, 80-3 and 80-4 mounted on the circumference of the chamber. Also, flow partitioning plates 180-1, 180-2, 180-3 and 180-4 are mounted in the vicinity of the respective composite nozzles 80-1, 80-2, 80-3 and 80-4. The composite nozzle 80-1 is connected to a controlled supply of reactive gas A; the composite nozzle 80-2 is connected to a controlled supply of an inert gas P; the composite nozzle 80-3 is connected to a controlled supply of a reactive gas B and the composite nozzle 80-4 is connected to a controlled supply of an inert gas P. During the operation of the ALCVP reactor, the first rotating susceptor 354a is driven by activating the external rotary mechanism, the temperature of the susceptors and the pressure ALCVP chamber 350 is maintained at a desired level while all the composite nozzles (80-1, 80-2, 80-3 and 80-4) operate continuously. The rotating susceptor temperature control mechanism is not specifically described for the ALCVP reactor 350 which is same as described in FIGS. 16-22.

It is specifically noted herein that in all the ALCVP reactor configurations described above (referring to FIGS. 16-22), the mechanism to control the ALCVP chamber pressure is not explicitly shown and described in detail. However, it is a necessary process variable for a thin film process, whether it is an atomic layer chemical vapor process or a high rate chemical vapor process, and to an individual skilled in the art the instruments and circuitry required to control the pressure during substrate processing is well known.

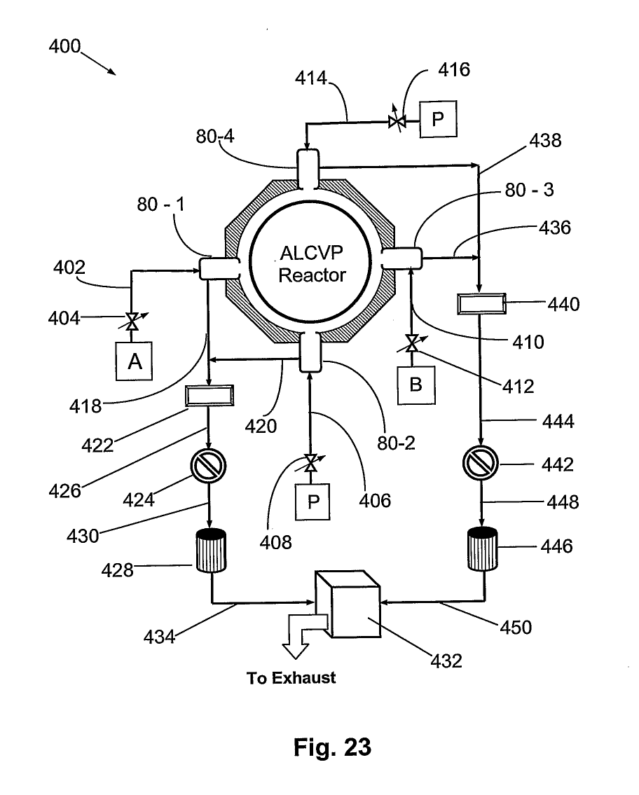

FIG. 23 is a schematic of an atomic layer chemical vapor processing system 400 comprising an ALCVP reactor 240 according to an embodiment of this invention with four composite nozzles 80-1, 80-2, 80-3, and 80-4 and with a downstream vacuum system arrangement. It is to be noted herein that a computerized control system to control various process parameters of the ALCVP system 400 is not shown in FIG. 23. However, to an individual skilled in the art, such would be known. It should be noted that the reactor 240 is shown by way of example only and the downstream vacuum system arrangement as shown in FIG. 23 is equally applicable to various other embodiments of the ALCVP reactor configurations described in this invention. The first composite nozzle 80-1 is connected to a controlled supply of a first reactive gas A through a first inlet pipe 402 and a first metering valve 404. The second composite nozzle 80-2 is connected to a controlled supply of an inert gas P through a second inlet pipe 406 and a second metering valve 408. The third composite nozzle 80-3 is connected to a controlled supply of a second reactive gas B through a third inlet pipe 410 and a third metering valve 412. The fourth composite nozzle 80-4 is connected to a controlled supply of an inert gas P through a fourth inlet pipe 414 and a fourth metering valve 416. The first exhaust pipe 418 from the first composite nozzle 80-1 and the second exhaust pipe 420 from the second composite nozzle 80-2 are connected together to a first gate valve 422. The first gate valve 422 is connected to the first throttle valve 424 by a first gate valve connector pipe 426. In turn, the first throttle valve 424 is connected to the first chemical precursor collection trap 428 through a first throttle valve connector pipe 430. Subsequently, the first chemical precursor collection trap 428 is connected to a vacuum pump 432 through a first chemical precursor collection trap pipe 434. Similarly, the third exhaust pipe 436 from the third composite nozzle 80-3 and the fourth exhaust pipe 438 from the fourth composite nozzle 80-4 are connected together to a second gate valve 440. The second gate valve 440 is connected to the second throttle valve 442 by a second gate valve connector pipe 444. In turn, the second throttle valve 442 is connected to the second chemical precursor collection trap 446 through a second throttle valve connector pipe 448. Subsequently, the second chemical precursor collection trap 446 is connected to the vacuum pump 432 through a second chemical precursor collection trap pipe 450.

It should be noted herein that it may be necessary to heat all the connector pipes leading from the substrate processing chamber to the filter/trap through the gate valve and throttle valve in order to prevent condensation of the reactive gases (chemical precursors) in the exhaust. Both the chemical precursor traps, 428 and 446 respectively, are provided with a constant flow of coolant to help condense the reactive gases/chemical precursors. Such an arrangement has several potentially highly valuable benefits. First, the chemical precursor collection traps also help remove the solid particulates from the respective gas streams, which is highly beneficial for vacuum pump and its operation. Second, the unused reactive gases are locally injected and locally and separately collected and can be isolated in relatively purer state. This feature has significance in potential chemical re-use and also in enhancing the overall process and system operating efficiency and to substantially reduce the downstream effluent stream and its post-processing. Finally, by implementing closed-loop connection methodology between the input gas quantity and the collected quantity in the respective chemical precursor collection traps, the input reactive gas quantity can be optimized so as to reduce the collection in the chemical precursor traps to a minimum level and help run the overall process economically.

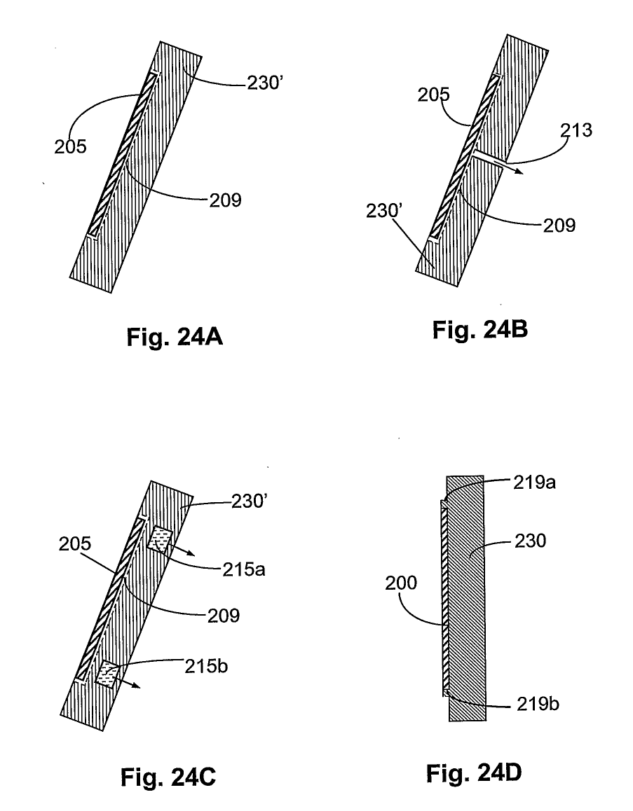

FIGS. 24A-24D illustrate various schematic arrangements for holding substrates on to susceptors while providing the substrate with excellent thermal contact. FIG. 24A is a schematic of an inclined plane of an octagonal susceptor 230′ with a recess 209 holding a planar substrate 205 within the recess 209. FIG. 24B illustrates a schematic of an inclined plane of the octagonal susceptor 230′ with a vacuum aperture 213 to hold the planar substrate 205 within the recess 209. During operation of the ALCVP reactor 300, the pressure within the cavity 209 is maintained lower than the chamber operating pressure by applying suction through purge gas exit port 295 (ref. FIG. 21). FIG. 24C illustrates a schematic of an inclined plane of the octagonal susceptor 230′ onto which the planar substrate 205 is held in the recess 209 with the help of two electrostatic chuck plates 215a and 215b respectively. FIG. 24D illustrates a schematic of the circular susceptor 230 with a flexible substrate 200 being held vertically on the circular susceptor 230 with the help of spikes 219a and 219b respectively.

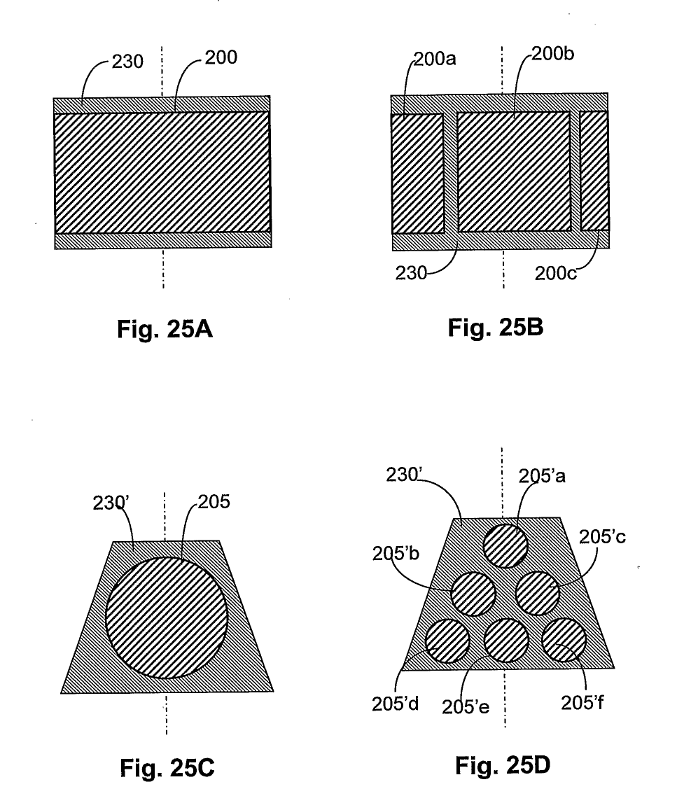

FIGS. 25A-25D illustrate various spatial arrangements of substrate placement on the face or facets of a susceptor. FIG. 25A illustrates the frontal view of a flexible substrate 200 being held onto the circular susceptor 230 which is substantially cylindrical in shape. FIG. 25B is a frontal view of the circular susceptor 230 onto which a plurality of substrates 200a, 200b, 200c are attached. FIG. 25C is the frontal view of a facet of the octagonal susceptor 230′ holding a planar substrate 205. FIG. 25D is the frontal view of a facet of an octagonal susceptor 230′ holding a plurality of circular shaped planar substrates 205′a, 205′b, 205′c, 205′d, 205′e and 205′f for atomic layer chemical vapor processing.

### Operation of the Apparatus of the Invention

All the configurations of the atomic layer chemical vapor processing apparatus of the invention as described in detail can be operated in dual mode. The first mode of operation of the apparatus is as an atomic layer chemical vapor processing reactor to process the substrate at one atomic layer precision and the second mode of operation is a high-speed chemical vapor processing reactor.

In the first mode of reactor operation, to begin with, a substrate or multiple substrates, as the case may be, are firmly placed onto the susceptor and the ALCVP reactor door is closed to obtain a stable and constant internal pressure environment with the help of the O-ring seal. All four flow partitioning plates are lowered in to the chamber towards the susceptor such that the lower edges of all the flow partitioning plates are held in a fixed position in close proximity to the rotating susceptor. The distance between the lower edge of the flow partitioning plate and the susceptor surface can vary within the range of 1-5 mm depending upon the nature of the process gas, substrate temperature and reactor pressure. The ALCVP reactor is evacuated by opening the gate valve and the throttle valve with vacuum pump operational. The upper and lower inert gas purge and the susceptor cavity purge gas flows are initiated. Simultaneously, substrate rotation is initiated. Subsequent to attainment of the desired angular speed, which is thereafter maintained constant in a particular process step, the second and fourth composite nozzles both employing an inert gas P are activated. Simultaneously, the substrate is heated to the desired temperature and its temperature is maintained constant by supplying electrical energy to the embedded heater in closed loop fashion. During this step, the chamber pressure is also adjusted and held constant with the help of a closed loop arrangement between the throttle valve and the pressure sensor. Subsequently, the composite nozzle employing the first reactive gas A is activated and immediately thereafter the second composite nozzle that employs the second reactive gas B is activated. Activation of a nozzle for the present invention involves initiating the flow from an inner linear injector and simultaneously employing the outer exhaust port to evacuate the excess gas from the vicinity of the substrate. The substrate is thus continuously processed by exposing sequentially to the first reactive gas A, the inert gas P, the second reactive gas B and the inert gas P to process a single atomic layer on its surface. Subsequent to achieving the desired level of substrate processing, the first and third composite nozzles employing reactive gases are de-activated and the substrate is cooled in the flow of the inert gas flow from the second and fourth composite nozzles respectively, to a desired temperature while it is being continuously rotated. Subsequently, the angular speed of substrate rotation is gradually reduced and substrate rotation is fully stopped. The flow partitioning plates are retracted (moved outward) from the substrate surface. The gate valve is closed and the chamber is brought to a desired pressure level to transfer the substrate out of the chamber by opening chamber door to the substrate transfer port.

In a second mode of the reactor operation, subsequent to activation of all four composite nozzles, the second composite nozzle employing the inert gas P is de-activated by switching off flow of inert gas P and also turning off the valve in the outer exhaust port. Deactivation of the second composite nozzle results in termination of the process of formation of first monolayer (atomic layer) by the first reactive gas A and the overall process transforms into a high rate chemical vapor processing. Optionally, the fourth composite nozzle, employing the inert gas P, is also.deactivated. Also, in high rate chemical vapor processing mode all the flow partitioning plates are held in retracted position such that their lower edges are substantially away from the susceptor surface.

As an example of operating speed of the ALCVP reactor as described above, the substrate width can be 30 cm and the length can be approx. 100 cm. Such a substrate can be wrapped around a susceptor of approximate diameter=100 cm/π, which is approximately=32 cm. Assuming each monolayer of a thin film material is 0.2 nm in thickness and angular speed of susceptor rotation is 1000 rotations/min., the atomic layer deposition rate of 200 nm/min.; can be achieved on an area of one-third of a meter. An ALCVP reactor can achieve deposition thickness of 1.0 micron (1000 nm) in five minutes on a substrate size of one third of square meter! The invention is explained in further detail through its applications as described in the following examples:

### Example—1

### Atomic Layer Deposition of Copper

Copper films can be deposited with one monolayer precision by employing cuprous halide with general formula CuX (X═F, Cl, Br and I) generated in-situ within the inner linear injector of the first composite nozzle, as described in the U.S. patent application Ser. No. 10/975,169; filed Oct. 27, 2004. The cuprous halide gas is subsequently combined with active hydrogen species (e.g., ionic species H⁺, free radicals H. and activated H₂*) derived from H₂ plasma. Alternately, CuX on the substrate surface can be combined with hydrogen free radicals (H.) obtained from a radical source connected to the inner linear injector of the second composite nozzle. For copper monolayer deposition process, the first and third composite nozzle each employs copper halide precursor while the second and fourth composite nozzles both employ species derived from hydrogen plasma or hydrogen free radicals to speed up the overall process.

The overall reaction is described as:

CuX+H⁺/H.→Cu+HX (2)

In the chemical process of copper halide reduction as described in equation (2), the active hydrogen species replace the inert gas P in a conventional four-step atomic layer deposition process. Alternate copper precursors that can be effectively used for this purpose are: Copper (II) hexafluoro-acetyl-acetonate [Cu(hfac)₂], Copper (II) 2,2,6,6,-tetramethyl 3,5-heptanedionate [Cu(thd)₂] among others.

### Example—2

### Deposition of Copper Indium Diselenide Alloy Films

Thin films of Copper Indium Diselenide can be deposited in ALD mode by employing one of the precursors of copper as described in example−1 above, which is combined with the appropriate precursor of indium such as halide of indium e.g., indium trichloride [InCl₃] which can be generated in-situ within the linear injector [ref. U.S. patent application Ser. No. 10/975,169 filed Oct. 27, 2004], tri-methyl indium [(CH₃)₃In], di-methly indium chloride [(CH₃)₂In—Cl], indium hexa-fluoro-pentanedionate [C₁₅H₃F₁₈O₆In] among others. The precursors of indium are not limited to the ones listed above. The preferred selenium precursor is H₂Se gas which can be generated in-situ from solid selenium and hydrogen as described in the U.S. patent application Ser. No. 10/975,169 filed Oct. 27, 2004. The overall chemical reaction for synthesis of copper indium diselenide thin films can be given as (for sake of simplicity the reaction is shown for chlorides and hydrogen selenide gas only):

CuCl+InCl₃+2 H₂Se→CuInSe₂+4 HCl Eq. (2)

Nitrogen can be employed as an inert gas for purge in the ALD process. The configurations of ALCVP reactors that can be used for this purpose are shown in FIG. 6A wherein dual inner linear injectors can be employed to inject CuCl and InCl₃ vapors in to the chamber. Also, the ALCVP reactor configuration as described in FIGS. 17 and 18 can be effectively employed for this purpose.

### Example—3

### Deposition of Copper Indium (Gallium) Selenide (CIGS) Graded Composition Films

Thin films of varying composition with thickness can be deposited in ALD mode by employing the ALCVP reactor configurations as described in FIGS. 17 and 18. The sources for copper and indium are as described, but are not limited to the ones, above. These can be combined with the appropriate gallium sources such as, but not limited to, tri-ethyl gallium [(CH₃)₃ Ga], diethyl-gallium chloride ((C₂H₅) Ga—Cl], and H₂Se with N₂ as the purge gas. During the ALD/CVD deposition process of Copper Indium (Gallium) Diselenide films, the flow of indium is increased that of gallium is proportionately decreased while maintaining the flow of H₂Se. Such a process sequence in ALD or in CVD mode is of significant valve to develop graded optical gap, large area and high quality solar absorber materials in which the composition and optical band-gap of the material can be tuned with respect to the film thickness.

### Example—4

### Deposition of Zinc Sulfide/Zinc Selenide Films

Thin films of ZnSe can be deposited by employing ZnCl₂ as a zinc source and H₂S or H₂Se as source of sulfur and selenium respectively. ZnCl₂ can be generated in-situ within an inner linear injector as described in the U.S. patent application Ser. No. 11/______ Alternatively, di-methyl zinc [(CH₃)₂Zn] can be employed as a zinc source.

### Example—5

### Deposition of Copper Indium (Gallium) Selenide and Zinc Sulfide/Zinc Selenide Bi-layer Films

CIGS is employed as an absorber layer and ZnSSe is a window layer in thin film photovoltaic solar cells. Bi-layer thin films of copper indium (gallium) selenide (CIGS)/ZnSSe thin films can be achieved by first depositing CIGS thin films as shown in example 3 above by employing an ALCVP reactor configuration as described in FIG. 17 wherein A₁=copper source, A₂=indium source and A₃=gallium/zinc source while B₁=selenium source and B₂=sulfur source. In such a process sequence, the ZnSSe film can be deposited on top of the CIGS film already formed within the same chamber without breaking vacuum. Either both CIGS and ZnSSe or one of the thin films can be deposited by ALD or CVD method. Such a process sequence can be of significant value to increase solar cell efficiency by preserving the integrity of the interface between the absorber layer and the window layer.

The invention has been shown and described with reference to specific embodiments, which should be construed as examples only and do not limit the scope of practical applications of the invention. Therefore, any changes and modifications in technological processes, construction, materials, shapes and components are possible, provided these changes and modifications do not depart from the patent claims. For example, the composite nozzle, substantially linear in shape can be replaced by a set of multiple, individual nozzles that span the height of the susceptor. The susceptor in several embodiments has been described as a round drum or a rotatable element with multiple facets and a polygonal cross-section. In at least one embodiment described above, however, the system uses two rotating drums and a substrate or substrate carrier passes around both drums. The susceptor is thus a transport mechanism within the chamber, and many sorts of transport mechanisms are possible and probable within the scope of the invention. Alternately, a single-point nozzle projecting the flow on to the full height of the susceptor can be effectively employed to cover the substrate. Also, a large variety of chemical processes can be developed by employing the apparatus and methods described above. Furthermore, the process sequence can be suitably modified according to process chemistry and the desired product; however, all such modifications will fall within the scope of the invention. The operation of such a reactor can be modulated over a wide range of process parameters such as, gas flow rates, substrate temperature, substrate rotation speed and chamber pressure. In addition to deposition, the invention is equally applicable to other broad areas of processing such as etching or removal of materials, stripping of photoresist, post-ash or post-etch cleaning of resides in microstructures, removing deposits on the inner surfaces of the processing chamber and so on. It thus encompasses a broad area of substrate processing and is referred to by the inventor as Atomic Layer Chemical Vapor Processing, “ALCVP” and the processing chamber is termed the ALCVP reactor. Moreover, the configurations of the invention as described are not restricted to a particular chemical process and a wide range of chemistries can be effectively performed within its scope. The substrate shape need not be necessarily restricted to round or rectangular in shape and may have a square, polygonal or any other shape. Also various combinations and arrangements of the composite nozzles different from those shown and described are possible. Moreover, the susceptor, apart from being circular and octagonal in cross section, can be polygonal in shape. In the case of a composite nozzle, the inner linear injectors are not necessarily cylindrical tubes and may have a conical or any other shape. Such apparatus and methods of substrate processing are taught in sufficient and enabling detail.

Moreover, in all the ALCVP reactor configurations described above, the susceptor can be supplied with an electromagnetic source of energy e.g., radio-frequency excitation and can also be biased appropriately to modulate the properties of the thin film being processed and also the nature of the chemical reactions taking place on the surface of the substrate. Alternatively, at least one of the inner linear injectors can be connected to a plasma source or one of the linear injectors may be also connected to a source of free radicals to facilitate thin film processing reactions at lower temperatures.

Also, in all the atomic layer chemical vapor processing apparatus configurations described above, the mode of operation of the apparatus can be switched in-situ from discrete atomic layer processing to high-rate chemical vapor processing (deposition, etching or surface modification) mode of operation. During the atomic layer chemical vapor processing mode, all the rectangular flow partitioning plates are lowered towards the substrate to help break the boundary layer being formed on the surface of the substrate while all the composite nozzles, employing reactive gases as well as inert gases, are set in operation. Whereas, the high-rate mode of operation can be realized by either switching off the inert gas flow towards the substrate and/or by moving all flow partitioning plates away from the substrate surface.

Furthermore, it is quite important to note that in all the configurations of the ALCVP apparatus of the invention reactive gases are injected locally and are also collected locally and separately. In the downstream piping arrangement, the exhaust arm of the first composite injector and the exhaust arm of second composite injector are both connected to a Y (or a T) shaped connector which is in turn connected to a vacuum pump through a throttle valve and a chemical precursor collection/condensation trap. Similar downstream piping arrangement is employed for the third and fourth composite injectors respectively. Such piping arrangement in the exhaust section of the ALCVP apparatus averts downstream mixing of highly reactive chemical precursors and significantly helps in the recovery of the unused portion of the precursors in relatively pure form for their potential reuse to realize significant operational savings. Also, such an arrangement also greatly reduces the quantity of downstream effluents, extent of waste remediation and costs associated with it. In addition, the various reactor configurations described herein also help optimize the chemical precursor consumption. A combination of these factors help substantially increase the overall process speed and also the operating efficiency of the apparatus described in the invention.

What is claimed is:

1. A thin-film processing apparatus, comprising:
a processing chamber with an exterior wall having an outer periphery and a connected evacuation subsystem;
a plurality of injection nozzles spaced apart around the outer periphery of the exterior wall, individual ones of the injection nozzles penetrating the chamber wall to bring processing gas from outside the chamber to the inside of the chamber, and distributing injected gas substantially in a linear pattern; and
a transport subsystem within the processing chamber carrying one or more substrates to be coated in a manner that the one or more substrates pass in close proximity to the plurality of injection nozzles in a sequential order and repeat the sequential passing while the transport subsystem operates.

2. The apparatus of claim 1 wherein individual ones of the injection nozzles have dedicated evacuation apparatus associated with the individual nozzle to remove excess injected gas in the immediate vicinity of that nozzle during operation.

3. The apparatus of claim 1 wherein the plurality of injection nozzles is a multiple of four, and in the sequential order a first in a set of four nozzles injects a first reactive gas to form a chemisorbed monolayer, a second in the set of four nozzles injects a first inert gas to purge remnant of the first reactive gas, a third in the set of four nozzles injects a second reactive gas to react chemically with the chemisorbed first reactive gas to form a monolayer of a film, and a fourth in the set of four nozzles injects a second inert gas to purge remnant of the second reactive gas. a set of four nozzles coupled with the repeated passage of the substrate in the sequence performing an atomic layer deposition process building a film on the substrate with monolayer precision.

4. The apparatus of claim 3 wherein the multiple is one and the number of nozzles in the sequence is four.

5. The apparatus of claim 1 wherein the chamber is substantially round, the outer periphery is a diameter of the chamber, and the transport subsystem comprises a drum rotating within the substantially round chamber.

6. The apparatus of claim 5 wherein a substrate is a flexible panel wrapped on the drum the drum height and the panel width being substantially equal, and wherein individual ones of the plurality of nozzles in linear extent span substantially the width of the substrate, with the drum rotating to carry a point on the substrate in a direction substantially at a right angle to the linear pattern of injection.

7. The apparatus of claim 1 wherein the chamber has front and a back substantially flat wall portions, and rounded end portions, and the transport subsystem comprises two drums of substantially the same diameter rotating at a common angular velocity.

8. The apparatus of claim 7 wherein the substrate is a flexible panel passing around both drums in a continuous loop, and wherein individual ones of the plurality of nozzles in linear extent span substantially the width of the substrate, with the drum rotating to carry a point on the substrate in a direction substantially at a right angle to the linear pattern of injection.

9. The apparatus of claim 1 wherein the chamber is substantially round, the outer periphery is a diameter of the chamber, and the transport subsystem comprises a drum of polygonal cross-section rotating within the substantially round chamber.

10. The apparatus of claim 9 wherein flat portions of the drum of polygonal cross section carry individual flat substrates.

11. A method for processing a thin film, comprising steps of:
(a) mounting a plurality of injection nozzles spaced apart around the outer periphery of wall of a processing chamber connected to an evacuation subsystem, with individual ones of the injection nozzles penetrating the chamber wall to bring processing gas from outside the chamber to the inside of the chamber, and distributing injected gas substantially in a linear pattern;
(b) Arranging at least one substrate to be coated on a transport subsystem within the processing chamber in a manner that the one or more substrates pass in close proximity to the plurality of injection nozzles in a sequential order and repeat the sequential passing while the transport subsystem operates.

12. The method of claim 11 including evacuating excess injected gas by a dedicated evacuation apparatus at individual ones of the injection nozzles in the immediate vicinity of that nozzle during operation.

13. The method of claim 11 wherein the plurality of injection nozzles is a multiple of four, and in the sequential order a first in a set of four nozzles injects a first reactive gas to form a chemisorbed monolayer, a second in the set of four nozzles injects a first inert gas to purge remnant of the first reactive gas, a third in the set of four nozzles injects a second reactive gas to react chemically with the chemisorbed first reactive gas to form a monolayer of a film, and a fourth in the set of four nozzles injects a second inert gas to purge remnant of the second reactive gas. a set of four nozzles coupled with the repeated passage of the substrate in the sequence performing an atomic layer deposition process building a film on the substrate with monolayer precision.

14. The method of claim 13 wherein the multiple is one and the number of nozzles in the sequence is four.

15. The method of claim 11 wherein the chamber is substantially round, the outer periphery is a diameter of the chamber, and the transport subsystem comprises a drum rotating within the substantially round chamber.

16. The method of claim 15 wherein a substrate is a flexible panel wrapped on the drum the drum height and the panel width being substantially equal, and wherein individual ones of the plurality of nozzles in linear extent span substantially the width of the substrate, with the drum rotating to carry a point on the substrate in a direction substantially at a right angle to the linear pattern of injection.

17. The method of claim 11 wherein the chamber has front and a back substantially flat wall portions, and rounded end portions, and the transport subsystem comprises two drums of substantially the same diameter rotating at a common angular velocity.

18. The method of claim 17 wherein the substrate is a flexible panel passing around both drums in a continuous loop, and wherein individual ones of the plurality of nozzles in linear extent span substantially the width of the substrate, with the drum rotating to carry a point on the substrate in a direction substantially at a right angle to the linear pattern of injection.

19. The method of claim 11 wherein the chamber is substantially round, the outer periphery is a diameter of the chamber, and the transport subsystem comprises a drum of polygonal cross-section rotating within the substantially round chamber.

20. The method of claim 19 wherein flat portions of the drum of polygonal cross section carry individual flat substrates.
